(19) United States
(12) Patent Application Publication
(10) Pub. No.: US 2025/0086366 A1
(43) Pub. Date: Mar. 13, 2025

(54) COMPUTER IMPLEMENTED METHOD FOR SIMULATING AN AERIAL IMAGE OF A MODEL OF A PHOTOLITHOGRAPHY MASK USING A MACHINE LEARNING MODEL

(71) Applicant: Carl Zeiss SMT GmbH, Oberkochen (DE)

(72) Inventors: Martin van Driel, Muenchen (DE); Niklas Georg, Haiger (DE); Carsten Schmidt, Jena (DE)

(21) Appl. No.: 18/829,459

(22) Filed: Sep. 10, 2024

(30) Foreign Application Priority Data
Sep. 12, 2023 (DE) 102023124581.3

(51) Int. Cl. G06F 30/32

(52) U.S. Cl. CPC G06F 30/32

(57) ABSTRACT

The invention relates to a computer implemented method for simulating an aerial image of a model of a photolithography mask illuminated by incident electromagnetic waves, the method comprising: obtaining the model of the photolithography mask; simulating the propagation of the incident electromagnetic waves through the model of the photolithography mask using a machine learning model, wherein the machine learning model maps the model of the photolithography mask to a representation of an electromagnetic field generated by the incident electromagnetic waves on the photolithography mask; obtaining the aerial image of the model of the photolithography mask by applying a simulation of an imaging process. The invention also relates to corresponding computer programs, computer-readable media and systems.

### CROSS-REFERENCE TO RELATED APPLICATION

This application claims benefit under 35 U.S.C. § 119 (a) of German patent application 10 2023 124 581.3, filed on Sep. 12, 2023, which is incorporated herein by reference in its entirety.

### TECHNICAL FIELD

The invention relates to a computer implemented method, a computer-readable medium, a computer program product and corresponding systems for simulating aerial images of models of photolithography masks. The method, computer-readable medium, computer program product and systems can be utilized for quantitative metrology, defect detection in photolithography masks, assessment of defect relevance in photolithography masks, for photolithography mask improvement, for system simulation or for process control, process monitoring or process improvement.

### BACKGROUND

A wafer made of a thin slice of silicon serves as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patterns are subject to several influences. One of the most crucial steps is the photolithography process.

Photolithography is a process used to produce patterns on the substrate of a wafer. The patterns to be printed on the surface of the substrate are usually generated by computer-aided-design (CAD). From the design, for each layer a photolithography mask is generated, which contains a magnified image of the computer-generated pattern to be etched into the substrate. The photolithography mask can be further adapted, e.g., by use of optical proximity correction techniques. During the printing process an illuminated image projected from the photolithography mask is focused onto a photoresist thin film formed on the substrate. A semiconductor chip powering mobile phones or tablets comprises, for example, approximately between 80 and 120 patterned layers. In the past, when photolithography required less precision, the circuit layout equaled the mask pattern which equaled the wafer pattern.

Due to the growing integration density in the semiconductor industry, photolithography masks have to image increasingly smaller structures onto wafers. The aspect ratio and the number of layers of integrated circuits constantly increases and the structures are growing into 3^{rd} (vertical) dimension. The current height of the memory stacks is exceeding a dozen of microns. In contrast, the feature size is becoming smaller. The minimum feature size or critical dimension is below 20 nm, or even below 10 nm, for example 7 nm or 5 nm, and is approaching feature sizes below 3 nm in near future. While the complexity and dimensions of the semiconductor structures are growing into the 3^{rd} dimension, the lateral dimensions of integrated semiconductor structures are becoming smaller. Producing the small structure dimensions imaged onto the wafer requires photolithography masks or templates for nanoimprint photolithography with ever smaller structures or pattern elements. The production process of photolithography masks and templates for nanoimprint photolithography is, therefore, becoming increasingly more complex and, as a result, more time-consuming and ultimately also more expensive. With the advent of EUV photolithography scanners, the nature of masks changed from transmission-based patterning to reflection-based patterning.

Today, the minimum feature size on the mask has reached sub-wavelength dimensions. Consequently, the so-called optical proximity effect caused by non-uniformity of energy intensity due to optical diffraction during the exposure process occurs. As a result, images formed on the substrate do not faithfully reproduce the patterns on the photolithography mask.

Therefore, many applications require an aerial image of the photolithography mask, which simulates the radiation intensity distribution at the substrate level. In this way, the aerial image allows for an analysis of the semiconductor structures that will be printed onto the substrate during the printing process. However, the generation of an aerial image is time-consuming and expensive. Therefore, methods for simulating aerial images based on a model of a photolithography mask have become important.

Among these methods, there are time-consuming rigorous simulations such as finite difference time domain (FDTD) or rigorous coupled wave analysis (RCWA), and fast approximations such as the thin element approximation (TEA). Due to the heavy computational load for full-chip applications, rigorous simulation is not typically used in commercial computational photolithography software. The thin element approximation (TEA) assumes that the thickness of the structures on the photolithography mask is very small compared to the wavelength, and that the widths of the structures on the photolithography mask are very large compared to the wavelength. However, as lithographic processes use radiation of shorter and shorter wavelengths, and the structures on the patterning device become smaller and smaller and grow into the vertical dimension, these assumptions do not hold anymore. Interaction of the incoming radiation with the absorber structures leads to mask 3D effects, which must be taken into account by the simulation. Therefore, the TEA yields inaccurate aerial images for radiation of short wavelength.

A typical mask 3D effect is, for example, mask shadowing. The chief ray angle (CRA) specifies the angle between the optical axis and the normal vector of the mask surface. The present EUV projection systems, for example, employ a CRA of 6°. Mask shadowing occurs due to the height of the absorber structures and the non-telecentric illumination at mask level, which modulates the captured intensity from the shadowed mask area through the reflective optics onto the wafer. At the wafer level, this causes asymmetric shadowing, an image shift and size bias depending on the feature orientation, and a shift of the process window.

Another mask 3D effect are phase shifts caused by the diffraction at the absorber structures. These phase effects generate imaging effects, which are very similar to phase deformations caused by wave aberrations of the projection systems.

Another mask 3D effect can be attributed to the reflective character of EUV photolithography masks. The dominant part of the reflected light originates from the multilayer, which is designed to provide a high reflectivity over a sufficiently large range of incidence angles. However, there is also some reflected light from the top of the absorber causing double images.

These mask 3D effects cannot be ignored during the lithography process. However, rigorous simulations methods such as finite difference time domain (FDTD) or rigorous coupled wave analysis (RCWA) that take into account mask 3D effects are computationally not feasible.

Therefore, there is a need for an accurate and fast simulation method for aerial images of photolithography masks.

A known method for simulating an aerial image of a photolithography mask is disclosed in U.S. Pat. No. 10,209,615 B2. The method uses a thin mask image as input and simulates the near field image using a neural network. Due to the use of the neural network no rigorous simulations are required and, thus, the computation time is reduced. The neural network is trained using thin mask images and corresponding near field images that can be obtained using rigorous simulation methods. However, thin mask images represent the mask as a 2D image, thereby ignoring its thickness and topographical structures and any mask 3D effects, in particular in case of short wavelengths. In addition, training of the neural network requires large amounts of training data. This training data has to be generated using rigorous simulation methods with very long runtimes. Therefore, even if inference is fast-training the neural network is still very time-consuming. Furthermore, the loss function penalizes deviations of the near field images obtained using the neural network from the simulated near fields, but the predictions of the neural network may not be consistent with the underlying physical principles that generated the simulated near fields.

It is, therefore, an aspect of the invention to obtain a simulation method for aerial images with increased accuracy. It is another aspect of the invention to obtain a simulation method for aerial images that requires low computation time. Another aspect of the invention is to reduce the required memory. It is another aspect of the invention to reduce the required user effort and expert knowledge. It is another aspect of the invention to obtain an aerial image simulation method which is applicable to transmission-based and reflection-based photolithography masks. A further aspect of the invention is to improve photolithography mask design without the need to actually print a wafer. Another aspect of the invention is to detect defects in photolithography masks with high accuracy and at low computation times. Another aspect of the invention is to assess the relevance of defects detected in photolithography masks with high accuracy and at low computation times. Another aspect of the invention is to detect edge placement errors of structures on photolithography masks.

The aspects are achieved by the invention specified in the independent claims. Advantageous embodiments and further developments of the invention are specified in the dependent claims.

### SUMMARY

Embodiments of the invention concern computer implemented methods, a computer-readable medium, a computer program product, and corresponding systems for simulating aerial images of models of photolithography masks or for detecting defects and assessing the relevance of defects in photolithography masks.

A first embodiment of the invention involves a computer implemented method for simulating an aerial image of a model of a photolithography mask, the photolithography mask comprising a mask carrier and a grating, the grating comprising absorber structures and non-absorber structures forming a pattern on at least a portion of the mask carrier, the photolithography mask comprising an absorber section extending between an absorber plane and a mask carrier plane of the photolithography mask and a mask carrier section extending between the mask carrier plane and a base plane of the photolithography mask, wherein the photolithography mask is illuminated by incident electromagnetic waves, the method comprising: obtaining the model of the photolithography mask wherein the model of the photolithography mask comprises an image containing image elements, in particular pixels or voxels, that each contain one or more property values at a corresponding location of the photolithography mask, and wherein the spatial resolution of the image is configured, such that at least one image element corresponds to a location in the photolithography mask containing two or more different property values for the same property of the photolithography mask, and/or such that image elements differ in their physical size; simulating the propagation of the incident electromagnetic waves through the model of the photolithography mask using a machine learning model, wherein the machine learning model maps the model of the photolithography mask to a representation of an electromagnetic field generated by the incident electromagnetic waves on the model of the photolithography mask; and obtaining the aerial image of the model of the photolithography mask by applying a simulation of an imaging process of a photolithography system or optical metrology system within a projection section to the representation of the electromagnetic field in a near field plane next to the absorber plane, wherein the projection section extends between the near field plane and a wafer plane. The simulated aerial image can be used for defect detection and verification of photolithography masks, for example, for defect detection in a photolithography mask, for improving the design of a photolithography mask, for assessing the relevance of defects in a photolithography mask or for detecting edge placement errors of structures on a photolithography mask. Based on the computed aerial image various important metrics for lithography can then be evaluated, for example, critical dimension (CD), normalized image log-slope (NILS)—or by computing a defocus stack of aerial images, also the best focus and/or depth of focus.

According to an embodiment of the invention, the simulated electromagnetic waves are incident on the base plane, propagated within the mask carrier section of the photolithography mask from the base plane to the mask carrier plane, and within the absorber section of the photolithography mask from the mask carrier plane to the absorber plane. In this way, the computer implemented method for simulating an aerial image can be applied to transmission-based photolithography masks, e.g., DUV photolithography masks.

According to an embodiment of the invention, the mask carrier comprises a multilayer in the form of a stack of optical thin films for reflecting the electromagnetic waves, and the simulated electromagnetic waves are incident on the absorber plane, propagated within the absorber section of the photolithography mask from the absorber plane to the mask carrier plane, reflected within the multilayer in the mask carrier section of the photolithography mask and propagated within the absorber section of the photolithography mask from the mask carrier plane to the absorber plane. In this way, the computer implemented method for simulating an aerial image can be applied to reflection-based photolithography masks, e.g., EUV photolithography masks.

According to an embodiment of the invention, the mask carrier comprises a glass substrate, and the simulated electromagnetic waves are incident on the absorber plane, partially reflected from the absorber plane, and partially propagated within the absorber section of the photolithography mask from the absorber plane to the mask carrier plane, reflected at the mask carrier plane of the photolithography mask and propagated within the absorber section of the photolithography mask from the mask carrier plane to the absorber plane. In this way, the computer implemented method for simulating an aerial image can be applied to reflection-based measurements of DUV photolithography masks.

In each of the aforementioned embodiments, further reflections and interference effects at other material interfaces are also taken into account.

The photolithography mask may have an aspect ratio of between 1:1 and 1:4, preferably between 1:1 and 1:2, most preferably of 1:1 or 1:2. The photolithography mask may have a nearly rectangular shape. The photolithography mask may be preferably 5 to 7 inches long and wide, most preferably 6 inches long and wide. Alternatively, the photolithography mask may be 5 to 7 inches long and 10 to 14 inches wide, preferably 6 inches long and 12 inches wide.

A “model” of the photolithography mask refers to a representation of the photolithography mask or a section thereof. The model can, for example, comprise a computer readable file, such as a CAD file or a GDS file, or a technical drawing, a set of polygons representing the structures of the photolithography mask or a section thereof. A model of a photolithography mask can comprise material information, e.g., complex refractive indices of materials contained in the photolithography mask, electric permittivities, magnetic permeabilities, or derived representations. A model of a photolithography mask can comprise parameters describing dimensions of structures in the photolithography mask, e.g., the thicknesses of the layers in the multilayer of an EUV mask or the thickness of absorber layers, or the dimension of the absorber structures. A model of a photolithography mask can comprise parameters describing the location of structures in the photolithography mask, e.g., the location of absorber structures or layers in the multilayer. A model of a photolithography mask can comprise parameters describing the shape of structures in the photolithography mask, e.g., the shape of the absorber structures such as side wall angles or corner rounding, etc. A model of a photolithography mask can comprise an image, e.g., a 2D image or a 3D image (e.g., a volume of voxels or a number of 2D slices of a volume), that represents properties of the photolithography mask. The image can contain one, two or more channels. The image can comprise image elements, e.g., pixels or voxels. The properties of the photolithography mask can comprise material properties, e.g., refractive indices, electric permittivities, magnetic permeabilities, or derived representations. The model of a photolithography mask can comprise descriptions of the structures within the photolithography mask, e.g., in the form of curves, contours, polygons, Splines, NURBS, Bezier curves, etc.

The model of the photolithograph mask preferably describes the photolithography mask at least partially in a dimension orthogonal to the mask carrier plane. The model of the photolithography mask can comprise one or more different sections of the photolithography mask, for example the absorber section and/or the mask carrier section. The one or more different sections can be arranged at different depths with respect to the normal of the mask carrier plane. For example, the model of the photolithography mask can comprise sections of the absorber section and/or of the mask carrier section and/or of the absorber plane and/or of the mask carrier plane. In particular, the model can comprise sections of the absorber section and of the mask carrier section.

A machine learning model is used to simulate the propagation of the electromagnetic waves within the photolithography mask. In this way, time-consuming rigorous simulations of the physical processes are not required. Instead, the machine learning model learns during training to map the model of the photolithography mask to a representation of an electromagnetic field generated by the incident electromagnetic waves on the model of the photolithography mask. During inference, i.e., during the application of the method after training, no time-consuming simulations are required, since the machine learning model already derived this knowledge during the training phase. Therefore, the method for simulating an aerial image of a model of a photolithography mask according to this invention is much faster than rigorous simulations.

In order to accurately simulate the propagation of the electromagnetic waves within the photolithography mask, a high resolution of the model of the photolithography mask is generally required to accurately model the small structure sizes at nm scale within the photolithography mask. The absorber section, for example, contains a grating comprising absorber structures and non-absorber structures of different sizes, angles and distances. In case of an EUV photolithography mask, the mask carrier section contains a multilayer comprising a number of thin layers of different materials and different thicknesses even below 1 nm. Thus, to accurately model the propagation of the electromagnetic waves within the photolithography mask, a sufficiently large resolution of the model of the photolithography mask is required in order to represent structures at small scale and various configurations. Experiments have shown that the error in the simulated near fields and aerial images is larger than 1%, if the model of the photolithography mask contains an image comprising image elements that represent physical dimensions larger than 0.5 nm in case of binary characteristic functions representing the different materials in the model of the photolithography mask. However, a large resolution of the model of the photolithography mask leads to large memory requirements and increased computation times. Therefore, methods to decrease the required resolution of the model of the photolithography mask are beneficial.

To this end, the model of the photolithography mask comprises an image containing image elements, in particular pixels or voxels, that each contain one or more property values at a corresponding location of the photolithography mask. There are two ways to reduce the resolution of the image: 1) at least one image element corresponds to a location in the photolithography mask containing two or more different property values for the same property of the photolithography mask (e.g., an image element contains two or more material properties), and 2) image elements differ in their physical size. Both ways can be used in combination or alternatively. In this way, the number of image elements and, thus, the computation time is reduced. In 1) image elements can contain two or more different structures with different properties (e.g., different material properties). In this way, the image elements can contain structure boundaries without loss of accuracy. Thus, the resolution becomes independent of the structure sizes and structure boundaries within the model of the photolithography mask, and it does not have to be adapted to the smallest structure size. In 2) the spatial resolution can vary in different parts of the image leading to different physical sizes of the image elements. For example, regions of the model containing larger structures can be represented by image elements with larger physical sizes, whereas regions with smaller structures can be represented by image elements with smaller physical sizes. Both ways allow a reduction of the number of image elements and, thus, of the computation time of the method.

A representation of an electromagnetic field generated by the incident electromagnetic waves on the photolithography mask can refer to the (complex) electric field E or the (complex) scattered electric field E_{sc}=E−E_{inc}, where E_{inc} denotes the incident electric field. A complex electromagnetic field can be represented for example, in terms of the real and imaginary part, or the amplitude and phase, etc. A representation of an electromagnetic field can refer to the (complex) magnetic field H or the (complex) scattered magnetic field H_{sc}=H−H_{inc}, where H_{inc} denotes the incident magnetic field. A representation of an electromagnetic field can comprise the envelope of the total or scattered electric field or of the total or scattered magnetic field, for example the total electric field envelope

$$\frac{E}{{e}^{- i k} i n {c}^{\cdot r}}$$

where the fast-varying electric field is demodulated by the fast-varying component e^{-ik}^{_{inc}}^{·r}, k_{inc} denotes the incident wave-vector and r the spatial coordinate vector. The envelope is finally multiplied with the phase term to obtain the electric field E. A representation of an electromagnetic field can comprise measurements derived from the electromagnetic field, e.g., diffraction orders, the spectrum, the far field or the intensity field, etc. The representation of the electromagnetic field within the photolithography mask can refer to the electromagnetic field within the photolithography mask, to a section of the electromagnetic field within the photolithography mask, to an electromagnetic field next to the photolithography mask, e.g., a near field, etc. A representation of an electromagnetic field can comprise representations of the electromagnetic field for different spatial directions. For example, a representation of an electromagnetic field can comprise a 2D or 3D image containing one, two or more channels, such that the 2D or 3D image comprises a representation of the electromagnetic field in each spatial direction, e.g., the complex electric field in x and y or in x, y and z direction yielding a 2D or 3D image with four or six channels.

An optical metrology system refers to a system which measures an aerial image of at least a part of a lithography mask, or quantities which can be derived from the aerial image, for example critical dimension (CD), normalized image log-slope (NILS), edge placement, defects, etc.

In case of a photolithography system, a wafer plane refers to a plane within the resist on top of a wafer if the wafer was placed in the photolithography system. In case of an optical metrology system, a wafer plane refers to a plane in which the camera sensors are located.

According to a preferred embodiment of the invention, the machine learning model was trained using a loss function comprising one or more partial differential equations (PDEs) describing properties of the representation of the electromagnetic field within the photolithography mask. Machine learning models with loss functions comprising PDEs that describe physical principles are also called physics-informed neural networks. Preferably, the one or more partial differential equations are derived from Maxwell's equations or from a Helmholtz equation. These can be used to model the propagation of electromagnetic waves within an inhomogeneous medium comprising different materials. In this way, the trained machine learning model generates predictions that are consistent with the underlying physical principles of the electromagnetic field within the photolithography mask. In addition, the user effort is strongly reduced, since training data can be generated automatically by simply generating models of photolithography masks. The corresponding representations of the electromagnetic fields are not required as part of the training data—instead, the loss function of the machine learning model can comprise the residual of the one or more PDEs that are used to evaluate the simulated electromagnetic fields.

According to an example, the model of the photolithography mask comprises an image in the form of a cross section image comprising properties of a cross section of the photolithography mask. In this way, the different sections of the photolithography mask, e.g., the absorber section and the mask carrier section, can be represented in the model that is used as input to the machine learning model. Thus, the propagation of the electromagnetic waves within the different sections of the photolithography mask can be learned by the machine learning model, thereby increasing the accuracy of its predictions. In order to represent a 3D model of a photolithography mask an image comprising multiple cross section images can be processed by the machine learning model, either at the same time or sequentially.

According to an example, the model of the photolithography mask comprises an image in the form of a voxel volume comprising properties of a section of the photolithography mask, e.g., a voxel volume comprising material properties of the section of the photolithography mask. Each voxel can, for example, comprise one or more properties of the section of the photolithography mask. In this way, a 3D model of a photolithography mask can be represented and used as input to the machine learning model. By using voxel-based models, spatial correlations between neighboring slices of the photolithography mask can be modeled, and the electromagnetic field can be simulated for the full 3D model of the photolithography mask by the machine learning model. In this way, the accuracy of the predictions of the machine learning model, of the simulated near fields and of the aerial images is improved.

In an example, the image elements of the image of the model of the photolithography mask contain one or more property values of material properties within the photolithography mask. The properties of the materials can, for example, comprise refractive indices, electric permittivities, magnetic permeabilities, or derived representations, e.g., normalized values such as relative permittivity values that are normalized to the range [0,1] using the minimum and maximum relative permittivity values. The refractive indices can be indicated as complex numbers, such that the imaginary part contains the attenuation, while the real part accounts for refraction. In particular, in case of absorbing materials within the photolithography mask complex numbers are beneficial to model the attenuation of the electromagnetic waves.

In an example, the image elements of the image of the model of the photolithography mask contain characteristic function values of materials within the photolithography mask. For each material in the photolithography mask, the material distribution can be modeled as a characteristic function that contains the value 1 in locations comprising the material and the value 0 in other locations. Thus, a characteristic function indicates the presence or absence of a material at different locations of the photolithography mask. A characteristic function, thus, describes a material property.

In a preferred example, the characteristic functions can also contain values within an interval, e.g., non-binary values within the interval [0,1], in case of two or more different materials are contained in the same pixel or voxel of the model of the photolithography mask. For example, if a pixel or voxel corresponds to a location in the photolithography mask containing two or more different materials, the characteristic function for each of the materials contains a value within the interval [0,1] such that the sum of the values amounts to 1. In this way, the pixel or voxel grid and the pixel or voxel size become independent of the material boundaries within the photolithography mask. Thus, the simulation of the electromagnetic field does not require small physical sizes of the image elements, e.g., below 1 nm. Instead, image elements with larger physical sizes below the wavelength, e.g., close to the wavelength, are sufficient to obtain accurate predictions, thereby saving computation time.

In an example, the model of the photolithography mask comprises two or more channels. For example, each channel can comprise a characteristic function indicating the presence of a specific material at each location. Alternatively, the model of the photolithography mask can comprise refractive indices of the material at each location, and the refractive indices can be indicated using complex numbers. To this end, the real part and the imaginary part can each make up a channel of the model of the photolithography mask. Alternatively, the real part and the imaginary part can be encoded sequentially or alternatingly in a single channel, other ways of encoding can be used, or machine learning models that handle complex inputs, e.g., a complex-valued neural network.

The machine learning model can be configured and trained in various ways. For example, the machine learning model can comprise a random forest, a decision tree, a regression model (e.g., a linear regression model, a polynomial regression model, a ridge regression model, etc.), a support vector regression model, a neural network, a neural operator, etc. It uses a model of the photolithography mask as input that is mapped to a representation of an electromagnetic field generated by the incident electromagnetic waves on the photolithography mask as output. Preferably, the machine learning model is implemented using parallel processing, e.g., by use of GPUs or TPUs, since many of the operations within a machine learning model can usually be carried out in parallel. In this way, the computation time is reduced during training and during inference.

In a preferred embodiment, the machine learning model comprises a neural network, in particular a deep neural network, a neural operator, a convolutional neural network, a conditional generative adversarial neural network, a Transformer, etc. Neural networks, in particular deep neural networks, are modeled after the human brain and have been successfully used to solve difficult modeling tasks in the recent past. Instead of requiring a user to define modeling rules, the neural network learns from the training data in a data-driven way. Thus, the trained model is optimally and automatically adapted to the modeling task. Neural networks, in particular deep neural networks, are able to learn complex relations between the input and the output of a machine learning model. Therefore, by using a neural network for simulating the propagation of the electromagnetic waves within the photolithography mask the accuracy of the simulated near fields and aerial images is improved. In addition, neural networks are very fast during inference, since a single forward pass is sufficient to obtain the output. Since the operations within each layer during the forward pass usually can be carried out in parallel, the neural network can be implemented using parallel processing, e.g., using GPUs or TPUs, thereby obtaining very short computation times. Furthermore, by using a neural network the effort for the user is reduced as no expert knowledge of the relations within the data is required for training the neural network.

In an example, the machine learning model comprises a neural operator. A neural operator is a neural network that learns a mapping between infinite dimensional function spaces (instead of functions between finite dimensional vector spaces). Neural operators can, thus, be used to approximate the solution operators raised in PDEs. Instead of learning a mapping from the input space to the output space from training data comprising pairs of models of photolithography masks and simulated electromagnetic fields, a neural operator is trained to solve a PDE by including the residual of the PDE in the loss function. In this way, the generated predictions of the neural operator are consistent with the physical principles underlying the predictions. Thus, the accuracy of the predictions is improved. Furthermore, the user effort is reduced, since the training data only comprises models of photolithography masks, but not the corresponding simulated representations of the electromagnetic fields. These are not required, since the PDE is contained in the loss function that is used to evaluate the predictions of the neural operator. As rigorous simulations of electromagnetic fields require long computation time, the computation time for training the neural operator is strongly reduced. Furthermore, the effort to generate training data for a neural operator is reduced compared to standard training procedures of neural networks.

In an example, the machine learning model comprises a convolutional neural network (CNN). A convolutional neural network is a neural network that comprises at least one convolutional layer. Convolutional neural networks use one or more convolutional layers that apply different kinds of learned filters to the input. Since, the filters are learned from training data in a data-driven way they are optimally adapted to the input data. By applying cascades of learned filters to the input, the CNN is able to extract low-level and high-level features that are specifically adapted to the modeling task. In this way, the accuracy of the predictions of the CNN and, thus, of the simulated near fields and aerial images is improved.

According to a preferred example, Floquet Bloch boundary conditions on at least a pair of opposite boundaries of the model of the photolithography mask that are orthogonal to the mask carrier plane are used. For example, in case of a model in form of a 2D cross section image with horizontal mask carrier plane, opposite boundaries that are orthogonal to the mask carrier plane are the vertical boundaries of the 2D cross section image. For example, in case of a model in form of a 3D image with horizontal mask carrier section, opposite boundaries that are orthogonal to the mask carrier plane comprise the vertical boundary planes in y/z direction and in x/z direction. In the case that a) the structures within the model of the photolithography mask are periodic and b) the incident electromagnetic plane wave has a phase shift with respect to opposite boundaries of the model of the photolithography mask due to its incident angle, the electric field generated by the incident electromagnetic wave has the same phase shift at the opposite boundaries and is, thus quasi-periodic, according to the Floquet Bloch theorem. Thus, the arbitrary illumination angle of the incident electromagnetic waves implies that the simulated electromagnetic field is quasi periodic according to the Floquet Bloch Theorem, that means periodic with an additional phase shift a. To accurately model the quasi periodic electromagnetic field, Floquet Bloch boundary conditions are implemented by using circular padding in the convolutions of the CNN at least one pair of opposite boundaries that are orthogonal to the mask carrier plane and multiplying the padded values with a phase shift induced by the incident angle of the electromagnetic waves on the photolithography mask. The incident angle can be measured with respect to the normal of the absorber plane. In this way, the accuracy of the predicted near fields and aerial images is improved.

According to an example, the machine learning model comprises a neural network with an encoder-decoder architecture. An encoder-decoder architecture can comprise an encoder and a decoder, only an encoder or only a decoder. By using an encoder the input can be mapped to a lower dimensional feature space (called bottleneck). The decoder then maps the features within the lower dimensional feature space to the desired output. By using a lower dimensional feature space, the information in the input is compressed such that only the most meaningful information for the learning task is preserved. In this way, the accuracy of the predictions of the neural network is improved. In addition, the computation time is reduced, since only the training of the neural network requires longer time, but the inference is fast.

In an example, the machine learning model comprises a neural network with a U-Net architecture. A U-Net architecture is an encoder-decoder architecture with additional skip connections between layers of the encoder and layers of the decoder. A U-Net is an image-to-image model that transforms some kind of image (the model of the photolithography mask) into another image (the representation of the electromagnetic field). The additional skip connections can be used to directly access information in the encoder before it is mapped to the latent space. In this way, specific details of the input can be preserved that can be used by the decoder. Thus, the accuracy of the near fields and aerial images simulated by the neural network is improved. In addition, the computation time is reduced, since only the training of the neural network requires longer time, but the inference is fast.

In an example, the machine learning model comprises a neural network with at least one attention mechanism, e.g., a Transformer machine learning model. An attention mechanism is a part of a neural network that is used to consider local or global context of parts of the input.

The term “attention mechanism” refers to a computational method that is part of a machine learning method that transforms input data to output data. The computational method is used for recognizing relationships between parts of the input data that are relevant for the transformation. To recognize relationships between parts of the input data, the attention mechanism can transform an element of the input data into a new representation, thereby making use of one or more other elements of the input data and their similarity to the element. The transformation can comprise a similarity function and an aggregation function, wherein the similarity function assesses the similarity of an element to one or more other elements in the input data, and the aggregation function maps the element and the one or more other elements and their similarities to the new representation of the element. The aggregation function can generate the new representation of the element using a weighted combination of the one or more other elements in the input data, wherein the weights depend on the similarities of the element to the one or more other elements. An attention mechanism can have at least one trainable parameter, preferably for pre-processing elements of the input data such that the similarity function is applied to the pre-processed elements. The at least one trainable parameter can define at least one projection matrix which is used to pre-process the elements of the input data. Throughout the aforementioned definition of the term “attention mechanism”, instead of elements of the input data, representations of the elements of the input data can be processed.

In contrast to convolutional layers or fully-connected layers, e.g., in CNNs, the weights applied to the elements of the input data depend on the input data, more precisely on the similarity of each element to the other elements of the input data, instead of being fixed after training. Furthermore, in contrast to convolutional operations, the attention mechanism does not require a fixed sequence of the elements in the input data. Instead, context windows of dynamic or global size can be implemented instead of using context windows of fixed size as in case of convolutions. Finally, in contrast to fully-connected layers, the attention mechanism does not require a fixed number of elements in the input data but can be applied to input data sets of arbitrary size. An attention mechanism can, thus, be understood as a convolution with input data dependent weights and a context window of arbitrary size. For example, the context window can comprise the complete input data. In case of an imaging dataset, the input data can, for example, comprise a sequence of patches that forms a partition of the imaging dataset.

By using at least one attention mechanism in the machine learning model, dependencies of the electromagnetic field on different sections of the model of the photolithography mask, e.g., on material properties in different sections, can be taken into account. By using attention mechanisms, this spatial context is not limited to the local receptive field of a convolution, but can comprise large contexts or even the complete input data, i.e., the global context. Thus, by using at least one attention mechanism, the accuracy of the predicted electromagnetic field is improved.

This is particularly beneficial, as the electromagnetic field within a section of the photolithography mask is related to the model of the photolithography mask, e.g., to material properties, in other sections of the photolithography mask. In this way, the accuracy of the predictions of the neural network and, thus, of the near fields and aerial images is improved.

In a preferred embodiment, the machine learning model computes the representation of the electromagnetic field generated by the incident electromagnetic waves on the model of the photolithography mask for any given incident angle of the electromagnetic waves. To this end, the machine learning model can comprise several sub-machine learning models that are each trained for a specific incident angle. Alternatively, a single machine learning model can be trained that can handle different incident angles of the electromagnetic waves. In this way, the user effort can be reduced as only a single machine learning model has to be trained to simulate the propagation of electromagnetic waves of arbitrary incident angles within the photolithography mask.

In an example, the incident angle is an input parameter of the machine learning model. An input parameter refers to a parameter that is not learned but indicated, e.g., by a user, and is used by the machine learning model in some way. By use of the input parameter, the machine learning model can be parameterized on the incident angle. During training, the training data can comprise the corresponding incident angle such that the machine learning model can learn relationships between the incident angle and the other parameters of the machine learning model. By using the incident angle as input parameter, the learning task is simplified and the accuracy of the simulated near fields and aerial images is improved.

In an example, the machine learning model comprises a neural network, and the incident angle of the electromagnetic waves is used as an input parameter in one of the layers of the neural network. For example, the incident angle can be used as an additional parameter in the input layer. Alternatively, the incident angle can be used as additional parameter in any of the other layers of the neural network. In case the neural network comprises an encoder-decoder architecture, the incident angle of the electromagnetic waves can be used as an input parameter in one of the layers of the encoder. The incident angle can, for example, be used as an input parameter in a first, second or third convolution layer of the encoder. The incident angle can also be used as an input parameter in the bottleneck. In this way, the adaptability of the neural network to different incident angles is improved, and the optimization of the loss function during training is simplified. Thus, the accuracy of the predictions of the neural network and, thus, of the simulated near fields and aerial images is improved.

According to an example, at least one image element corresponds to a location in the photolithography mask containing two or more different material property values for the same material property. The image can, for example, be a 2D image comprising image elements in the form of pixels, or the image can be a 3D image in the form of a voxel volume comprising image elements in the form of voxels. By using at least one image element that corresponds to a location in the photolithography mask containing two or more different material property values for the same material property, different structures in the model of the photolithography mask can be represented by a single image element. Thus, the spatial resolution of the image is independent of the physical size of the structures in the model of the photolithography mask. In this way, the spatial resolution can be adapted to meet computation time requirements. Thus, the computation time for training and inference of the machine learning model is reduced.

According to an aspect of the example, the material property value of the at least one image element that corresponds to a location in the photolithography mask containing two or more different material property values for the same material property indicates an effective material property value of the two or more different material property values for the same material property. The effective material property value within an image element that contains structures of two or more different material property values can be computed using a mean value, in particular a harmonic or an arithmetic mean value, of the material property values weighted by the proportion of the area or volume of the image element containing the material. Material properties comprise, for example, the electric permittivity, the magnetic permeability or the refractive index, etc. By using the effective material property value, the different material property values contained in an image element can be represented by a single value. Thus, the spatial resolution of the image is independent of material boundaries, and the physical image element size can be larger than 0.5 nm. In this way, the computation time is reduced during training and inference of the machine learning model.

Alternatively, the image can contain two or more channels, each channel representing a different material property, and the value of an image element in a specific channel corresponds to the material property value of the specific material property at the corresponding location in the photolithography mask. In addition, for each material property within the photolithography mask, the proportion of the volume of the image element corresponding to the specific material can be indicated in an additional channel.

According to an example, the model of the photolithography mask comprises an image containing image elements, in particular pixels or voxels, wherein the physical sizes of image elements differ, e.g., of at least two image elements. The physical size of an image element refers to the physical dimensions of the portion of the photolithography mask that are represented by the pixel. By using pixels of different physical sizes, the spatial resolution of the model of the photolithography mask can be modeled independently of the underlying physical dimensions of the structures. The physical sizes of the image elements can, for example, be configured such that structure boundaries coincide with image element boundaries, such that image elements only contain a single material. In this way, the accuracy of predictions of the machine learning model and, thus, of the simulated near fields and aerial images is improved. Furthermore, the computation time is reduced. The spatial resolution of the image can even be configured to fulfill a required computation time.

In an example, the model of the photolithography mask comprises an absorber section, and the physical sizes of at least some of the image elements in the absorber section are configured such that boundaries of these image elements coincide with boundaries of absorber structures in the absorber section. In particular, the physical sizes of image elements in the absorber section in directions parallel to the absorber plane (x and y direction), can be configured such that at least some image element boundaries coincide with boundaries of absorber structures. In this way, the absorber structures can be accurately modeled in the image without requiring an increased spatial resolution, thereby leading to higher accuracies of the predictions at low computation times.

In an example, the model of an EUV photolithography mask comprises a multilayer, and the physical sizes of image elements differ in at least two different layers of the multilayer. In particular, the physical sizes of at least some of the image elements are configured such that boundaries of these image elements coincide with boundaries of layers in the multilayer. For example, the physical sizes of image elements in the multilayer in the vertical direction (z direction) can be configured such that the image element boundaries coincide with the boundaries of the different layers of the multilayer. In this way, the different layers within the multilayer can be accurately modeled in the image without requiring an increased spatial resolution, thereby leading to higher accuracies of the predictions at low computation times.

For example, in case of an EUV mask, each layer of the multilayer in the mask carrier section can be represented by a single line (in case of a 2D image) or a single plane (in case of a 3D image), such that the vertical dimension of the image elements of different layers of the multilayer correspond to different physical thicknesses of the layers. Alternatively, the layers of the multilayer can contain different numbers of lines or planes of image elements. Preferably, the physical thicknesses of the image elements in the lines or planes are configured such that the boundaries of layers within the multilayer coincide with the physical layer boundaries. In this way, the different layers within the multilayers can be accurately modeled in the image without requiring an increased spatial resolution, thereby leading to higher accuracies of the predictions at low training and computation times.

According to an embodiment of the invention, a computer implemented method for simulating an aerial image of a model of an EUV photolithography mask, the photolithography mask comprising a mask carrier and a grating, the grating comprising absorber structures and non-absorber structures forming a pattern on at least a portion of the mask carrier, the photolithography mask comprising an absorber section extending between an absorber plane and a mask carrier plane of the photolithography mask and a mask carrier section extending between the mask carrier plane and a base plane of the photolithography mask, wherein the mask carrier section comprises a multilayer in the form of a stack of optical thin films for reflecting the electromagnetic waves, and wherein the photolithography mask is illuminated by incident electromagnetic waves, the method comprising: obtaining the model of the photolithography mask; simulating the propagation of the incident electromagnetic waves through the model of the photolithography mask using a machine learning model, wherein the machine learning model maps the model of the photolithography mask to a representation of an electromagnetic field generated by the incident electromagnetic waves on the photolithography mask, and wherein the machine learning model simulates the propagation of the electromagnetic waves within the absorber section of the photolithography mask, and wherein the propagation of the electromagnetic waves within the multilayer is computed analytically or with a numerical method not involving machine learning; and obtaining the aerial image of the model of the photolithography mask by applying a simulation of an imaging process of a photolithography system or optical metrology system within a projection section to the representation of the electromagnetic field in a near field plane next to the absorber plane, wherein the projection section extends between the near field plane and a wafer plane. In this way, the computation time is reduced, since the propagation of the electromagnetic waves does not have to be simulated by the machine learning model. In addition, the machine learning model requires less parameters and a smaller architecture, thereby simplifying the learning task, reducing the training and computation times, and improving the accuracy of the predictions.

In an example, the propagation of the electromagnetic waves within the multilayer is computed using a boundary condition that describes the reflection of the electromagnetic waves at a plane parallel to the mask carrier plane within the mask carrier section, in particular at the mask carrier plane. In this way, the reflection is described in a simple and accurate way leading to short computation times and accurate predictions of the machine learning model.

The propagation of the electromagnetic waves within the multilayer can, for example, be implemented using an absorbing boundary condition, for example, a perfectly matched layer (PML) boundary condition, and a reflection term describing the electromagnetic waves reflected by the multilayer at a plane parallel to the mask carrier plane within the mask carrier section, in particular at the mask carrier plane. By using an absorbing boundary condition in combination with a reflection term, the reflection of the electromagnetic waves at the multilayer can be accurately modeled, since the absorbing boundary condition assumes the absorption of the electromagnetic waves, and the reflection term describes the analytically or with a numerical method not involving machine learning computed reflected part of the electromagnetic waves. Thus, the accuracy of the predictions is improved, and the machine learning model is simplified leading to lower training and computation times.

According to an embodiment of the invention, a computer implemented method for training a machine learning model for simulating the propagation of electromagnetic waves through a model of a photolithography mask as described in any of the embodiments above, comprises: generating models of photolithography masks and, optionally, incident angles of the electromagnetic waves incident on the photolithography masks, as training data, wherein each model of a photolithography mask comprises a mask carrier and a grating, the grating comprising absorber structures and non-absorber structures forming a pattern on at least a portion of the mask carrier, and wherein each model of a photolithography mask comprises an absorber section extending between an absorber plane and a mask carrier plane of the photolithography mask and a mask carrier section extending between the mask carrier plane and a base plane of the photolithography mask; and iteratively presenting one or more models of photolithography masks and, optionally, incident angles, from the training data to the machine learning model, evaluating the loss function and modifying the parameters of the machine learning model.

In an example, the loss function comprises one or more partial differential equations describing properties of the representation of the electromagnetic field within the photolithography mask. In this way, the predictions of the machine learning model are consistent with the physical principles underlying the learning task. Thus, the accuracy of the predictions is improved. In addition, the generation of training data is simplified, since the predicted representations of the electromagnetic fields can be evaluated by computing the residual of the one or more PDEs instead of comparing the representations of the predicted electromagnetic fields with computationally expensive rigorously simulated representations of electromagnetic fields. The training data can even be generated automatically, since only different models of photolithography masks and incident angles are required that can be automatically generated using simple rule-based randomized algorithms.

In an example, the one or more partial differential equations are derived from Maxwell's equations or from a Helmholtz equation. In this way, the accuracy of the predictions is improved, since Maxwell's equations or their simplified version in form of a Helmholtz equation describe the propagation of electromagnetic waves within an inhomogeneous medium.

In an example, the loss function is evaluated using an approximation scheme of derivatives of the representation of the electromagnetic field that takes into account the physical sizes of the image elements, in particular approximation schemes relying on finite differences or finite elements. By taking into account the physical sizes of the image elements when computing derivatives in the loss function, the physical sizes of the image elements can differ and, thus, the spatial resolution of the image can differ in different parts of the model. In this way, the number of image elements and the computation time can be reduced. Furthermore, at least some of the image elements can be configured such that their boundaries align with boundaries of structures in the photolithography mask, thereby leading to an improved accuracy of the approximation schemes and, thus, of the predictions of the machine learning model.

In an example, the machine learning model simulates the propagation of electromagnetic waves within the absorber section of the photolithography mask, and the loss function computes the propagation of the electromagnetic waves within the mask carrier section analytically or with a numerical method not involving machine learning. Due to the lower number of parameters in the machine learning model, the computation time during training and inference is reduced. In addition, numerical discretization errors in the mask carrier section are prevented and the learning task is simplified leading to more accurate predictions of the machine learning model and, thus, to improved simulated near fields and aerial images of the model of the photolithography mask.

In an example, the photolithography mask is an EUV photolithography mask, and the loss function comprises a boundary condition that describes the reflection of the electromagnetic waves at a plane parallel to the mask carrier plane within the mask carrier section, in particular at the mask carrier plane. By modeling the reflection at the mask carrier plane, no simulation of the electromagnetic waves within the multilayer of the EUV photolithography mask is required. Thus, the architecture of the machine learning model is simplified, computation time for training and inference is reduced and the accuracy of the predictions is improved.

In an example, the loss function comprises an absorbing boundary condition, in particular a perfectly matched layer (PML) boundary condition, and a reflection term describing the electromagnetic waves reflected by the multilayer at a plane parallel to the mask carrier plane within the mask carrier section, in particular at the mask carrier plane. The absorbing boundary condition can be used to absorb the incoming electromagnetic waves, whereas the reflection term can be used to model the reflected electromagnetic waves at the multilayer according to the laws of physics. In this way, a simple and accurate prediction of the electromagnetic field is achieved, and low computation times at the same time.

According to an example, the model describes the photolithography mask at least partially in a dimension orthogonal to the mask carrier plane. For example, the model describes the structure of the photolithography mask at least partially in a dimension orthogonal to the mask carrier plane. For example, the model of the photolithography mask comprises an absorber section and/or a mask carrier section. Since the absorber section and the mask carrier section both extend along the dimension orthogonal to the mask carrier plane of the photolithography mask, the model describes the photolithography mask at least partially in this dimension. Preferably, the model describes the photolithography mask in other dimensions as well, e.g., in one or more dimensions parallel to the mask carrier plane. In this way, the configuration of the mask in the vertical dimension including mask 3D effects including non-telecentricities, shifts of the best focus position, and image blur are taken into account in the simulation instead of using a thin mask image as a model of the photolithography mask. Thus, the propagation of the electromagnetic waves within the photolithography mask is simulated with high accuracy, in particular for short wavelengths as used with EUV photolithography masks.

The simulated aerial image of the model of the photolithography mask can be used in different ways.

For example, based on an accurate aerial image of a model of a photolithography mask, the design of the photolithography mask can be improved, and mask 3D effects can be mitigated, e.g., by modifying the design layout of the photolithography mask, or by modifying the absorber material and/or absorber thickness within the grating of the photolithography mask, or by applying optical proximity correction techniques to the photolithography mask, for example by adding sub resolution assist features, etc.

For example, the simulated aerial image can be used for defect detection. Given an acquired aerial image of a photolithography mask, the photolithography mask can be checked for defects by simulating an aerial image of the photolithography mask based on a model of the photolithography mask and the illumination and imaging settings of the optical inspection tool used to obtain the acquired aerial image, and by comparing the acquired aerial image to the simulated aerial image.

For example, the relevance of defects in an acquired charged particle beam image of a photolithography mask can be assessed by simulating an aerial image using the acquired charged particle beam image of the photolithography mask as a model of the photolithography mask and the illumination and imaging settings of the optical inspection tool used to obtain the acquired aerial image, and by assessing the relevance of the defects using the simulated aerial image. In particular, the defects in the charged particle beam image can be compared to the corresponding locations in the simulated aerial image. This saves a lot of time and resources, since no aerial image of the photolithography mask needs to be acquired.

For example, the simulated aerial image can be used to generate a digital twin of a machine, which uses acquired aerial images of photolithography masks. The digital twin of the machine is a digital simulation of the machine, which uses a method for simulating an aerial image of a model of a photolithography mask as described above to simulate the acquisition of an aerial image within the machine. The digital twin of the machine can be used for many different purposes, e.g., for specifying the functionality and the requirements of the machine, for presenting the functionality of the machine to the customer before the machine is built or delivered, or for accelerating the development of parts of the machine, for example of the user interface, etc.

In these applications, instead of acquiring an aerial image of the photolithography mask, a simulation of the aerial image of a model of the photolithography mask is used, thereby considerably reducing the computation time.

Therefore, a computer implemented method for detecting defects in a photolithography mask according to an embodiment of the invention comprises: obtaining an aerial image of the photolithography mask; simulating an aerial image of a model of the photolithography mask using a method for simulating an aerial image as described above; detecting defects in the photolithography mask by comparing the obtained aerial image to the simulated aerial image. In this way, simulated aerial images can be used to detect defects in a photolithography mask with high accuracy and at low computation times. This allows to improve the design of the photolithography mask without requiring the actual printing of a wafer.

A computer implemented method for assessing the relevance of defects in a photolithography mask according to an embodiment of the invention comprises: providing a charged particle beam image of the photolithography mask comprising one or more defects; simulating an aerial image of a model of the photolithography mask using a method for simulating an aerial image as described above, wherein the charged particle beam image is used as a model of the photolithography mask; assessing the relevance of the one or more defects in the photolithography mask using the simulated aerial image. The simulated aerial image can be compared to the charged particle beam image or to a reference image, e.g., an acquired or simulated aerial image. In addition or alternatively, the critical dimension (CD) of the simulated aerial image can be used to assess the relevance of defects. For example, locations, where the CD lies below a predefined threshold, can be marked as relevant defects. A CD of a device can be defined as the smallest width of a line or hole, or the smallest space between two lines or two holes. Thus, the CD regulates the overall size and density of the designed device. Due to an accurate and fast simulation of the electromagnetic near field the relevance of defects can be assessed accurately and at low computation times.

Simulating the imaging process can comprise resampling of the simulated electromagnetic near field. Thus, the spatial resolution of the simulated aerial image can be increased without notably increasing the runtime. In this way, aerial images of a spatial resolution comparable to those obtained by rigorous simulation methods can be obtained.

A computer-readable medium according to an embodiment of the invention has stored thereon a computer program executable by a computing device, the computer program comprising code for executing a method according to any of the previously described embodiments of the invention.

A computer program product according to an embodiment of the invention comprises instructions which, when the program is executed by a computer, cause the computer to carry out a method according to any of the previously described embodiments of the invention.

A system for simulating an aerial image of a model of a photolithography mask according to an embodiment of the invention comprises a data analysis device comprising at least one memory and at least one processor configured to perform the steps of a computer implemented method for simulating an aerial image of a model of a photolithography mask described above.

A system for detecting defects in a photolithography mask according to an embodiment of the invention comprises: a subsystem for obtaining an aerial image of the photolithography mask, a data analysis device comprising at least one memory and at least one processor configured to perform the steps of a computer implemented method for detecting defects in a photolithography mask described above.

A system for assessing the relevance of defects in a photolithography mask according to an embodiment of the invention comprises: a subsystem for obtaining a charged particle beam image of the photolithography mask, a data analysis device comprising at least one memory and at least one processor configured to perform the steps of a computer implemented method for assessing the relevance of defects in a photolithography mask.

The invention described by examples and embodiments is not limited to the embodiments and examples but can be implemented by those skilled in the art by various combinations or modifications thereof.

### BRIEF DESCRIPTION OF THE DRAWINGS

FIG. 1 illustrates an exemplary transmission-based photolithography system, e.g., a deep ultraviolet (DUV) photolithography system.

FIG. 2 illustrates the propagation of incoming electromagnetic waves through a transmission-based photolithography mask;

FIG. 3 illustrates an exemplary reflection-based photolithography system, e.g., an extreme ultra-violet light (EUV) photolithography system;

FIG. 4 illustrates the propagation of incoming electromagnetic waves through a reflection-based photolithography mask;

FIG. 5A shows the amplitude of a simulated electromagnetic near field of a photolithography mask using the rigorous coupled-wave analysis (RCWA) method;

FIG. 5B shows the amplitude of a simulated electromagnetic near field of a photolithography mask using the thin element approximation (TEA) method;

FIG. 6 shows a flowchart of a computer implemented method for simulating an aerial image of a model of a photolithography mask;

FIG. 7A shows a model of an EUV photolithography mask in form of a cross section image comprising properties of a cross section of the photolithography mask;

FIG. 7B shows a model of an EUV photolithography mask in form of a voxel volume containing properties of the photolithography mask;

FIGS. 8A and 8B illustrate the application of the Floquet Bloch theorem to opposite boundaries of a photolithography mask that are orthogonal to the mask carrier plane;

FIGS. 9A, 9B show a neural network with a U-Net architecture that maps a model of a photolithography mask in the form of a cross section image to a representation of an electromagnetic field within the cross section;

FIGS. 10A, 10B show a neural network with a U-Net architecture that maps a model of a photolithography mask in the form of a voxel volume to a representation of an electromagnetic field;

FIGS. 11A-11D illustrate a single neural network that generates representations of electromagnetic fields for arbitrary incident angles Θ of the electromagnetic waves on the photolithography mask;

FIGS. 12A-12C illustrate the variation of the shape of the absorber structures within the absorber section of the photolithography mask and the simulated representations of the electromagnetic fields;

FIGS. 13A-13C illustrate different models of the photolithography mask using one or more image elements that each correspond to a location containing two or more different material property values for the same material property;

FIGS. 14A and 14B illustrate the use of image elements of different physical sizes that coincide with the boundaries of the absorber structures within a model of a photolithography mask;

FIGS. 15A and 15B illustrate the use of image elements of different physical sizes that coincide with the boundaries of the layers of the multilayer in a model of an EUV photolithography mask;

FIGS. 16A and 16B illustrate the propagation of the incident electromagnetic waves by the machine learning model only within the absorber section of an EUV photolithography mask, whereas the propagation of the electromagnetic waves within the multilayer is computed analytically or with a numerical method not involving machine learning;

FIG. 17 illustrates an exemplary electromagnetic field that is simulated using a model of a photolithography mask in the form of a voxel volume comprising refractive indices of materials within the photolithography mask;

FIG. 18 illustrates a flow chart of a computer implemented method for training a machine learning model for simulating the propagation of electromagnetic waves through a model of a photolithography mask;

FIG. 19 illustrates the training progress for training a U-Net shown in FIGS. 9A, 9B;

FIG. 20 illustrates a computer implemented method for detecting defects in a photolithography mask;

FIG. 21 illustrates a computer implemented method for assessing the relevance of defects in a photolithography mask;

FIG. 22 illustrates a system for simulating an aerial image of a model of a photolithography mask according to an embodiment of the invention;

FIG. 23 illustrates a system for detecting defects in a photolithography mask according to an embodiment of the invention; and

FIG. 24 illustrates a system for assessing the relevance of defects in a photolithography mask according to an embodiment of the invention.

### DETAILED DESCRIPTION

In the following, advantageous exemplary embodiments of the invention are described and schematically shown in the figures. Throughout the figures and the description, same reference numbers are used to describe same features or components. Dashed lines indicate optional features.

The methods and systems herein can be used with a variety of photolithography systems, e.g., transmission-based photolithography systems 10 or reflection-based photolithography systems 10′.

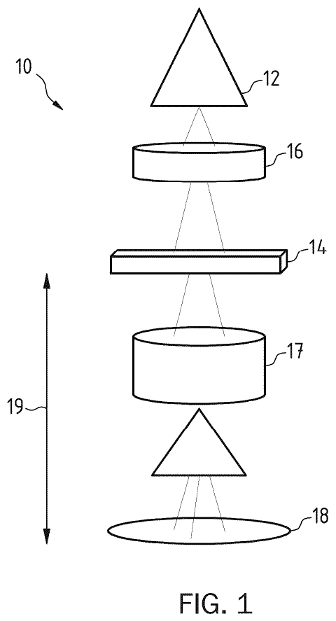

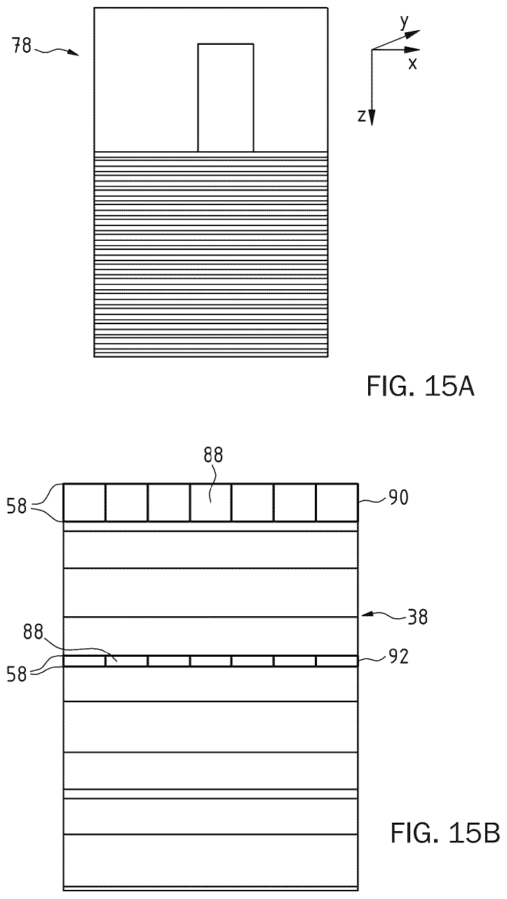

FIG. 1 illustrates an exemplary transmission-based photolithography system 10, e.g., a DUV photolithography system. Major components are a radiation source 12, which may be a deep-ultraviolet (DUV) excimer laser source, imaging optics which, for example, define the partial coherence and which may include optics that shape radiation from the radiation source 12, a photolithography mask 14, illumination optics 16 that illuminate the photolithography mask 14 and projection optics 17 that project an image of the photolithography mask pattern 92 (FIG. 15B) onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin(Gmax), wherein n is the refractive index of the media between the substrate of a wafer and the last element of the projection optics 17, and Gmax is the largest angle of the beam exiting from the projection optics 17 that can still impinge on the wafer plane 18.

In the present document, the terms “radiation” or “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 3-100 nm).

Illumination optics 16 may include optical components for shaping, adjusting and/or projecting radiation from the radiation source 12 before the radiation passes the photolithography mask 14. Projection optics 17 may include optical components for shaping, adjusting and/or projecting the radiation after the radiation passes the photolithography mask 14. The illumination optics 16 exclude the light source 12, the projection optics exclude the photolithography mask 14.

Illumination optics 16 and projection optics 17 may comprise various types of optical systems, including refractive optics, reflective optics, apertures and catadioptric optics, for example. Illumination optics 16 and projection optics 17 may also include components operating according to any of these design types for directing, shaping or controlling the projection beam of radiation, collectively or singularly.

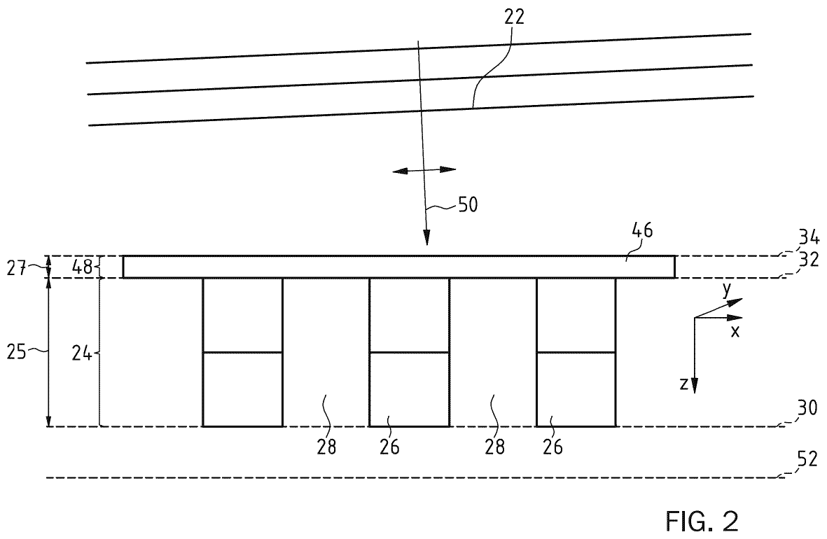

FIG. 2 illustrates the propagation of incoming electromagnetic waves 22 through a transmission-based photolithography mask 14, e.g., a DUV photolithography mask. The photolithography mask 14 has a mask carrier 48 and a grating 24. The mask carrier 48 is arranged in a mask carrier section 27 of the photolithography mask 14 and the grating 24 is arranged in an absorber section 25 of the photolithography mask 14. The grating 24 is formed by a combination of absorber structures 26 and non-absorber structures 28. The absorber structures 26 are made of one or more materials which absorb electromagnetic waves 22, e.g., titanium nitride or tantalum nitride, etc. The non-absorber structures 28 are made of one or more materials which absorb electromagnetic waves 22 to a lower degree than the absorber material. For example, the non-absorber structures 28 can comprise vacuum. In this document, the phrase “non-absorber structure” may refer to (i) a region of the mask made of one or more materials which absorb electromagnetic waves to a lower degree than the absorber material, or (ii) a region of the mask that is vacuum or has one or more gases that absorb electromagnetic waves to a lower degree than the absorber material. Thus, the grating 24 is an inhomogeneous medium. The absorber structures 26 and the non-absorber structures 28 are deposited on a mask carrier 48. The mask carrier 48 can comprise a substrate layer 46. The mask carrier 48 in the photolithography mask 14 is delimited by a mask carrier plane 32 and a base plane 34 which is preferably parallel to the mask carrier plane 32. The mask carrier plane 32 is a surface plane of the mask carrier 48. The base-plane 34 is a boundary plane through which the electromagnetic waves 22 enter the grating 24. The incoming electromagnetic wave 22 impinge on the base plane 34. The base plane 34 is forming an interface between the mask carrier 48 and the outside of the photolithography mask 14 through which the electromagnetic waves 22 propagate. The absorber structures 26 in the grating 24 of the photolithography mask 14 are delimited by the mask carrier plane 32 and an absorber plane 30. The absorber plane 30 is a boundary plane which contains the portion of the surface of the absorber structures 26, which is facing away from the mask carrier plane 32. Preferably, the absorber plane 30 is parallel to the mask carrier plane 32. The absorber section 25 of the photolithography mask 14 extends between the absorber plane 30 and the mask carrier plane 32 and is delimited by these planes. The mask carrier section 27 of the photolithography mask 14 extends between the mask carrier plane 32 and the base plane 34 and is delimited by the mask carrier plane 32 and the base plane 34.

For transmission-based photolithography masks 14 the simulated electromagnetic waves 22 are incident on the base plane 34, propagated within the mask carrier section 27 of the photolithography mask 14 from the base plane 34 to the mask carrier plane 32, and within the absorber section 25 of the photolithography mask 14 from the mask carrier plane 32 to the absorber plane 30.

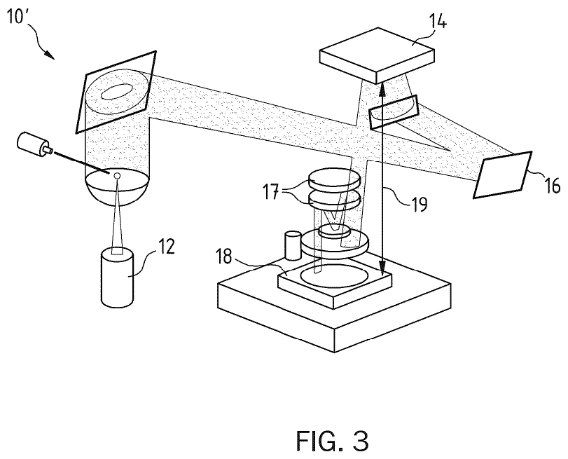

FIG. 3 illustrates an exemplary reflection-based photolithography system 10′, e.g., an extreme ultraviolet light (EUV) lithography system. Major components are a radiation source 12, which may be a laser plasma light source, illumination optics 16 which, for example, define the partial coherence and which may include optics that shape radiation from the radiation source 12, a photolithography mask 14, and projection optics 17 that project an image of the photolithography mask pattern 92 onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin(Gmax), wherein n is the refractive index of the media between the substrate of a wafer and the last element of the projection optics 17, and Gmax is the largest angle of the beam exiting from the projection optics 17 that can still impinge on the wafer plane 18.

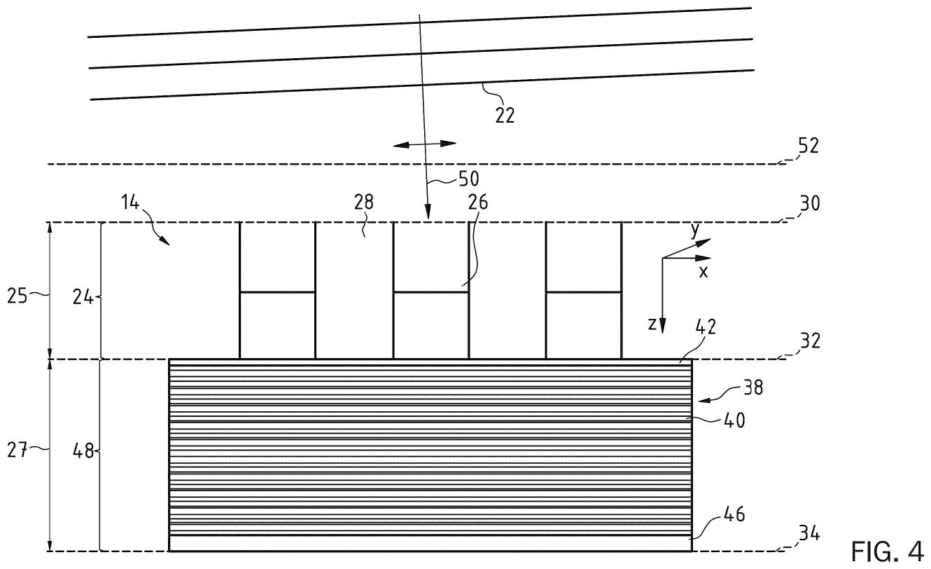

FIG. 4 illustrates the propagation of incoming electromagnetic waves 22 through a reflection-based photolithography mask 14, e.g., an EUV photolithography mask. The photolithography mask 14 has a mask carrier 48 and a grating 24. The mask carrier 48 is arranged in a mask carrier section 27 of the photolithography mask 14 and the grating 24 is arranged in an absorber section 25 of the photolithography mask 14. The grating 24 contains absorber structures 26 and non-absorber structures 28 forming a pattern 92 on at least a portion of the mask carrier 48 to be printed onto a wafer. The absorber structures 26 are made of one or more materials which absorb electromagnetic waves 22, e.g., titanium nitride or tantalum nitride, etc. The non-absorber structures 28 are made of one or more materials which absorb electromagnetic waves 22 to a lower degree than the absorber material. For example, the non-absorber structures 28 can comprise vacuum. Thus, the absorber structures 26 and the non-absorber structures 28 form an inhomogeneous medium. The absorber structures 26 and the non-absorber structures 28 are deposited on a mask carrier 48. The mask carrier 48 comprises a multilayer 38 in the form of a stack of optical thin films 40 for reflecting the electromagnetic waves 22. The mask carrier 48 can comprise a capping layer 42 and/or a substrate layer 46. The mask carrier 48 in the photolithography mask 14 is delimited by a mask carrier plane 32 and a base plane 34 which is preferably parallel to the mask carrier plane 32. The mask carrier plane 32 is a surface plane of the mask carrier 48. The absorber structures 26 in the grating 24 of the photolithography mask 14 are delimited by the mask carrier plane 32 and an absorber plane 30. The absorber plane 30 is a boundary plane which contains the portion of the surface of the absorber structures 26, which is facing away from the mask carrier plane 32. Preferably, the absorber plane 30 is parallel to the mask carrier plane 32.

The absorber plane 30 is a boundary plane through which the electromagnetic waves 22 enter the grating 24. The incoming electromagnetic waves 22 impinge on the absorber plane 30. The absorber plane 30 is forming an interface between the mask 14 and the outside of the photolithography mask 14 through which the electromagnetic waves 22 propagate. The absorber section 25 of the photolithography mask 14 extends between the absorber plane 30 and the mask carrier plane 32 and is delimited by these planes. The mask carrier section 27 of the photolithography mask 14 extends between the mask carrier plane 32 and the base plane 34 and is delimited by the mask carrier plane 32 and the base plane 34.

For reflection-based photolithography masks 14, the mask carrier 48 comprises a multilayer 38 in the form of a stack of optical thin films 40 for reflecting the electromagnetic waves 22, wherein the simulated electromagnetic waves 22 are incident on the absorber plane 30, propagated within the absorber section 25 of the photolithography mask 14 from the absorber plane 30 to the mask carrier plane 32, reflected within the multilayer 38 in the mask carrier section 27 of the photolithography mask 14 and propagated within the absorber section 25 of the photolithography mask 14 from the mask carrier plane 32 to the absorber plane 30.

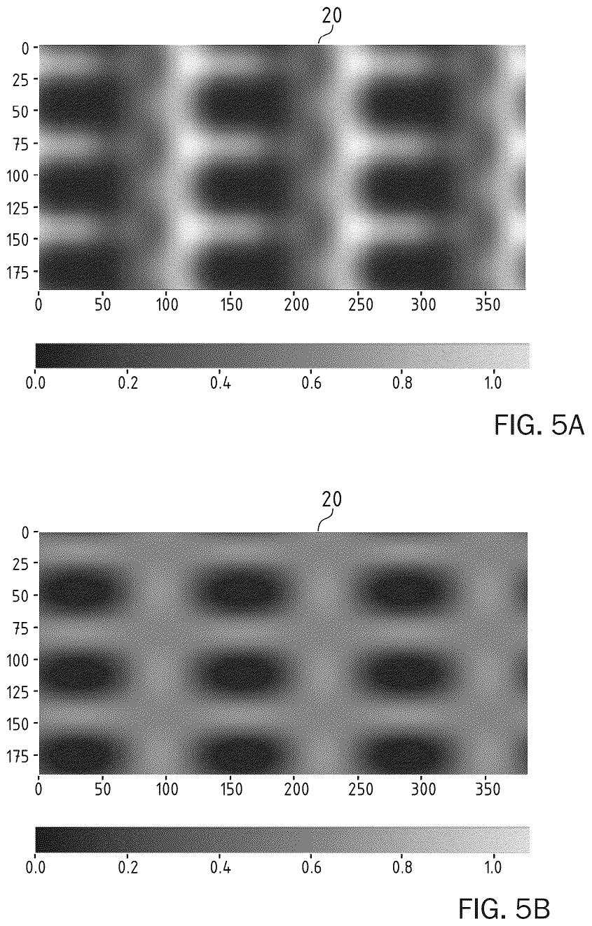

An electromagnetic near field 20 (FIGS. 5A, 5B) indicates the distribution of the electromagnetic waves 22 in a near field plane 52 next to the absorber plane 30 of the photolithography mask 14. Preferably, the near field plane 52 is parallel to the absorber plane 30 or to the base plane 34 of the photolithography mask 14. The near field plane 52 can, in general, be located anywhere between the absorber plane 30 and the wafer plane 18 or outside the photolithography mask. The notion “next to” refers to a distance between 0 and 1000 nm, preferably a distance between 0 and 100 nm, more preferably a distance between 0 and 50 nm, even more preferably a distance between 0 and 20 nm and most preferably a distance between 0 and 10 nm. In a preferred embodiment of the invention the near field plane 52 and the absorber plane 30 are identical.

An aerial image indicates the radiation intensity distribution in the wafer plane 18.

Known methods for simulating electromagnetic near fields 20 or aerial images either require large computation times or are not sufficiently accurate.

For simulating the interaction of electromagnetic waves 22 with a photolithography mask 14 the propagation of the electromagnetic waves 22 within the different layers of the photolithography mask 14 comprising different materials with different refractive indices has to be taken into account.

For simulating electromagnetic near fields 20, rigorous simulation techniques such as finite difference time domain (FDTD), the finite-element method (FEM) or the rigorous coupled wave analysis (RCWA) method are often used. For example, FIG. 5A shows the amplitude of a simulated electromagnetic near field 20 of a photolithography mask 14 using the rigorous coupled-wave analysis (RCWA) method. However, these methods are computationally extremely expensive, which makes these techniques not feasible for full-chip applications. A full mask simulation could even require several years.

FIG. 5B shows the amplitude of a simulated electromagnetic near field 20 of an EUV photolithography mask 14 for coherent oblique illumination at EUV wavelength using the thin element approximation (TEA) method. The thin element approximation method is an efficient algorithm to analyze diffractive optical elements. The TEA method assumes that the thickness of the structures on the photolithography mask 14 is very small compared to the wavelength of the incoming light and that the widths of the structures on the photolithography mask 14 are very large compared to the wavelength. However, as photolithographic processes use radiation of shorter and shorter wavelengths, and the structures on the photolithography mask 14 become smaller and smaller, the assumptions of the TEA method can break down. In this case the photolithography mask 14 cannot be approximated by a flat surface photolithography mask anymore. Instead, the interaction of the radiation at a wavelength below the height of the structures on the photolithography mask 14 leading to the so-called mask 3D effects must be taken into account. Therefore, a method for simulating an aerial image of a photolithography mask 14 is required, which is fast and accurate even for short wavelengths.

To decrease the computation time, attempts have been made to simulate near fields of photolithography masks using neural networks. Neural networks can require long training times, but are usually very fast in the inference phase. However, these approaches also assume a flat photolithography mask (thin mask) and, thus, cannot account for mask 3D effects, in particular for small wavelengths. It is, therefore, an aspect of the invention to simulate aerial images by simulating the propagation of electromagnetic waves incident on a photolithography mask accurately and at low computation times.

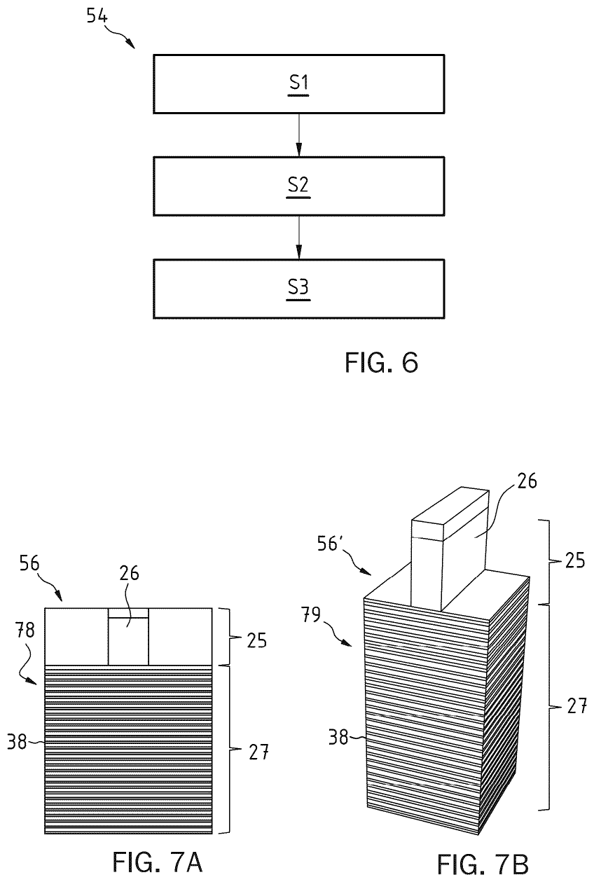

To meet these aspects, a computer implemented method for simulating an aerial image of a model of a photolithography mask according to an embodiment of the invention is described. FIG. 6 shows a corresponding flowchart. The computer implemented method 54 for simulating an aerial image of a model of a photolithography mask 14, the photolithography mask 14 comprising a mask carrier 48 and a grating 24, the grating 24 comprising absorber structures 26 and non-absorber structures 28 forming a pattern 92 on at least a portion of the mask carrier 48, the photolithography mask 14 comprising an absorber section 25 extending between an absorber plane 30 and a mask carrier plane 32 of the photolithography mask 14 and a mask carrier section 27 extending between the mask carrier plane 32 and a base plane 34 of the photolithography mask 14, wherein the photolithography mask 14 is illuminated by incident electromagnetic waves 22, comprises: obtaining the model of the photolithography mask 14 wherein the model 56, 56′ of the photolithography mask 14 comprises an image 78, 79 containing image elements 88 (FIG. 15B), in particular pixels or voxels, that each contain one or more property values at a corresponding location of the photolithography mask 14, and wherein the spatial resolution of the image 78, 79 is configured, such that at least one image element 88 corresponds to a location in the photolithography mask 14 containing two or more different property values for the same property of the photolithography mask 14, and/or such that image elements 88 differ in their physical size in a step S1; simulating the propagation of the incident electromagnetic waves 22 through the model of the photolithography mask 14 using a machine learning model, wherein the machine learning model maps the model of the photolithography mask 14 to a representation of an electromagnetic field generated by the incident electromagnetic waves 22 on the model of the photolithography mask 14 in a step S2; and obtaining the aerial image of the model of the photolithography mask 14 by applying a simulation of an imaging process of a photolithography system 10, 10′ or optical metrology system within a projection section 19 to the representation of the electromagnetic field 68 in a near field plane 52 next to the absorber plane 30, wherein the projection section 19 extends between the near field plane 52 and a wafer plane 18. The electromagnetic field in the near field plane 52 next to the absorber plane 30 is called near field 20.

As the grating 24 of the photolithography mask 14 comprises absorber structures 26 and non-absorber structures 28 forming an inhomogeneous medium, the simulation of the propagation of the electromagnetic waves 22 within the absorber section 25 takes into account the inhomogeneity of the grating material. Instead of using a thin mask model for simulating the electromagnetic field incident on the photolithography mask 14, the methods described herein use a model of the photolithography mask 14 that explicitly comprises different sections of the photolithography mask 14, e.g., the absorber section 25 and/or the mask carrier section 27. In this way, the machine learning model can use as input the model of the photolithography mask 14 that contains, for example, the material distribution within the different structures of the photolithography mask 14. The machine learning model can, thus, learn the relations between the structures of different materials and the representation of the electromagnetic field in the photolithography mask 14. Thus, the simulated representation of the electromagnetic field within the photolithography mask is of an increased accuracy. In addition, machine learning models can require longer computation times during training, but they are usually very fast during inference as only a single forward pass is required. Thus, by use of a machine learning model that uses an accurate model of the photolithography mask 14 highly accurate representations of electromagnetic fields and, thus, near fields and aerial images can be simulated at low computation times.

The computer implemented method 54 for simulating an aerial image of a model of a photolithography mask can be applied to transmission-based photolithography masks and reflection-based photolithography masks.

In a preferred embodiment, the machine learning model was trained using a loss function comprising one or more partial differential equations describing properties of the representation of the electromagnetic field within the photolithography mask 14. By directly including the partial differential equations in the loss function during training of the machine learning model, predictions of the machine learning model correspond to the underlying physical principles. Thus, the accuracy of the predictions and of the simulated aerial images is increased.

In an example, the one or more partial differential equations are derived from Maxwell's equations or from a Helmholtz equation. Maxwell's equations can be written in a simplified way as a Helmholtz equation in the photolithography setting. Thus, by using Maxwell's equations or a Helmholtz equation in the loss function during training of the machine learning model, the machine learning model learns to approximate the PDEs that describe the propagation of the electromagnetic waves within the different sections of the photolithography mask. In this way, the underlying physical principles are explicitly learned by the machine learning model, thereby increasing the accuracy of its predictions and, thus, the simulated near fields or aerial images. Furthermore, it is sufficient to include models of photolithography masks in the training data. No time-consuming rigorous simulations of electromagnetic fields corresponding to the models of the photolithography mask in the training data is required, since the residual of the PDEs can be used to evaluate the quality of the electromagnetic fields simulated by the machine learning model. Thus, the effort and time required for generating training data is strongly reduced.

The propagation of electromagnetic waves within a medium can be described by use of Maxwell's equations. Let ϵ₀ indicate the vacuum electric permittivity and ϵ(r, ω) a dielectric function characterizing the relative electric permittivity of a specific material within the photolithography mask. These relations are connected to the refractive index n(r, ω) of a material via ϵ(r, ω)=n(r, ω)², assuming the magnetic permeability of vacuum for simplicity. Based on these material relations and in the absence of free charges and currents, the time-harmonic Maxwell's equations read as

$$\begin{matrix}\begin{matrix}∇ \times E ( r , ω ) = i ω {μ}_{0} H ( r , ω ) , & ∇ \cdot H ( r , ω ) = 0 ,\end{matrix} \\ \begin{matrix}∇ \times H ( r , ω ) = - i {ωϵ}_{0} ϵ ( r , ω ) E ( r , ω ) , & ∇ \cdot ( ϵ ( r , ω ) E ( r , ω ) ) = 0 ,\end{matrix}\end{matrix} \qquad ( 1 )$$

where E indicates the electric field strength, H the magnetic field strength, r the spatial coordinate vector and ω the angular frequency.

Based on the Maxwell equations, the following equation can be derived for the electric field E of an electromagnetic wave:

$$Δ E ( r , ω ) + \frac{{ω}^{2}}{{c}^{2}} ϵ ( r , ω ) E ( r , ω ) = - ∇ \cdot ( \frac{∇ ϵ ( r , ω )}{ϵ ( r , ω )} \cdot E ( r , ω ) ) , \qquad ( 2 )$$

where c is the speed of light. The right-hand side couples the electric field components, which makes it hard to find solutions to this equation. Therefore, the right-hand side is preferably neglected. The neglection of the right-hand side remains valid if the following two assumptions are fulfilled: the considered optical system does not show a distinctive response depending upon the incident polarization, and there is no cross coupling between individual polarization components. For the lithography setting at short wavelengths, e.g., for EUV photolithography masks, there are two reasons for neglecting polarization and phononic effects, so these assumptions are valid. Firstly, the contrasts in the refractive index are low with respect to the different materials of the absorber structures and the non-absorber structures. Secondly, the height a of the absorber-structures and the non-absorber structures in the grating is larger than the wavelength λ, i.e.

$$\frac{a}{λ} \geq 2 .$$

Therefore, the right-hand side of equation (2) can, thus, be neglected resulting in the following Helmholtz equation

$$Δ E ( r , ω ) + \frac{{ω}^{2}}{{c}^{2}} ϵ ( r , ω ) E ( r , ω ) = 0. \qquad ( 3 )$$

FIGS. 7A and 7B illustrate different models 56, 56′ of an EUV photolithography mask. FIGS. 7A and 7B only show a portion of the model 56, 56′ for the sake of illustration. The models 56, 56′ can include information about the entire photolithography mask or only about a portion of the photolithography mask, e.g., about a slice or a cross-section of the photolithography mask. In this case, it can be assumed that the remaining part of the photolithography mask is identical to the portion of the photolithography mask represented by the model 56, 56′, e.g., that all slices of the photolithography mask are identical. Depending on the training data used to train the machine learning model the machine learning model can learn to handle different variants of models. The pattern of absorber structures 26 and non-absorber structures 28 define the mask pattern. The models 56, 56′ in FIGS. 7A and 7B describe the photolithography mask 14 in a dimension orthogonal to the mask carrier plane 32. Thus, in contrast to thin mask images, the models 56, 56′ contain a vertical dimension, i.e., a dimension orthogonal to the mask carrier plane 32. In particular, the models 56, 56′ contain different sections of the photolithography mask, that is an absorber section 25 and a mask carrier section 27. The models 56, 56′ contain a grating 24 within the absorber section 25 and a multilayer 38 within the mask carrier section 27. The models 56, 56′ in FIGS. 7A and 7B also describe the photolithography mask 14 in one, respectively, two dimensions parallel to the mask carrier plane 32 and in one direction orthogonal to the mask carrier plane 32. In FIG. 7A, the model 56 of the photolithography mask 14 comprises an image in the form of a cross section image 78 comprising properties of a cross section of the photolithography mask 14. The model 56 of the photolithography mask 14 can contain two or more cross section images that can be processed by a machine learning model, either at the same time or sequentially. For example, the model 56 can contain a cross-section image describing the structures of the photolithography mask in horizontal and vertical directions (a slice) as shown in FIG. 7A, and a cross-section image describing the mask pattern of the photolithography mask, e.g., a top view of the photolithography mask. The model 56 can also contain a cross-section image describing the structures of the photolithography mask in horizontal and vertical direction as shown in FIG. 7A and a design image describing the 2D photolithography mask pattern. In FIG. 7B, the model 56′ of the photolithography mask 14 comprises an image in the form of a voxel volume 79 comprising properties of the photolithography mask. In this way, the different sections of the photolithography mask are represented in the model 56, 56′ that is used as input to the machine learning model. Using accurate descriptions of the structures within the photolithography mask, in particular in vertical direction (z direction), the accuracy of the predictions of the machine learning model is improved.

The propagation of the electromagnetic waves within the photolithography mask depends on the materials within the photolithography mask. For example, Maxwell's equations in (1) and the Helmholtz equation in (3) contain dielectric functions ϵ(r, ω) characterizing specific materials within the photolithography mask. These functions are related to the refractive indices n(r, ω). By using material properties within the photolithography mask as input to the machine learning model, the machine learning model can learn to map specific material property distributions to representations of electromagnetic fields generated by the incident electromagnetic waves 22 on the photolithography mask 14. In this way, the accuracy of the simulated near fields 20 and aerial images can be improved.

In both, FIGS. 7A and 7B, the image elements 88 of the image 78, 79 of the model 56, 56′ of the photolithography mask 14 contain one or more property values of material properties within the photolithography mask 14. The image elements 88 can, for example, contain refractive indices of materials within the photolithography mask 14. Light propagation in absorbing materials can, for example, be described using a complex-valued refractive index. Thus, the refractive indices can be represented by complex numbers. The imaginary part then handles the attenuation, while the real part accounts for refraction. The machine learning model then maps models 56, 56′ of photolithography masks 14 that contain refractive indices, e.g., in the form of complex numbers represented as a 2D or 3D image comprising two channels, to representations of an electromagnetic field generated by the electromagnetic waves 22 incident on the photolithography mask 14. The output of the machine learning model is a representation of the electromagnetic field, for example, a 2D or 3D image comprising two or more channels, e.g., the real and imaginary parts of the electric field or of the scattered electric field, or the amplitude and phase of the electric field, or the magnetic field, etc. The scattered electric field has been found to be easier to learn for the machine learning model due to the lower complexity. However, other representations can be used as output of the machine learning model as well. Each representation can be obtained for one or more spatial dimensions of the electromagnetic field, e.g., x, y and z components of the real and imaginary parts of the electric field, thus yielding six channels.

Different machine learning models can be used for mapping a model 56, 56′ of a photolithography mask 14 to a representation of an electromagnetic field generated by incident electromagnetic waves 22 on the photolithography mask 14.

In an example, the machine learning model comprises a neural operator. A neural operator is a neural network that learns a mapping between infinite dimensional function spaces (instead of functions between finite dimensional vector spaces). Neural operator methods represent the solution map of parametric PDEs as an integral Hilbert-Schmidt operator, whose kernel is parametrized and learned from paired observations, either using local message passing on a graph-based discretization of the physical domain, or using global Fourier approximations in the frequency domain, as for example described in “Learning the solution of parametric partial differential equations with physics-informed DeepONets, Sifan Wang, Hanwen Wang, Paris Perdikaris, arXiv:2103.10974v1”. Neural operator methods are resolution independent. Thus, the model can be queried at an arbitrary input location. To achieve independence from spatial resolution, the neural operator can, for example, comprise two sub-networks to achieve an abstraction from the discretization of the input and output. A so-called branch net can be used to map the input to a latent representation, and a so-called trunk net can be used to extract latent representations at given coordinates at which the output functions are evaluated. Thus, the solution of PDEs such as Maxwell's equations in (1) or the Helmholtz equation in (3) can be obtained by training a neural operator, thereby improving the accuracy of the predicted near fields and aerial images and reducing the computation time.

According to an example, the machine learning model comprises a convolutional neural network (CNN). CNNs are a class of neural networks that use convolutions in at least one of their layers. A convolution represents a filtering operation with a filter of a specific size called receptive field that is applied to the output of the previous layer. During training, the filters are learned from training data to optimally solve the given task by minimizing the loss function. By using a CNN, the accuracy of the simulated near field and the aerial image is improved.

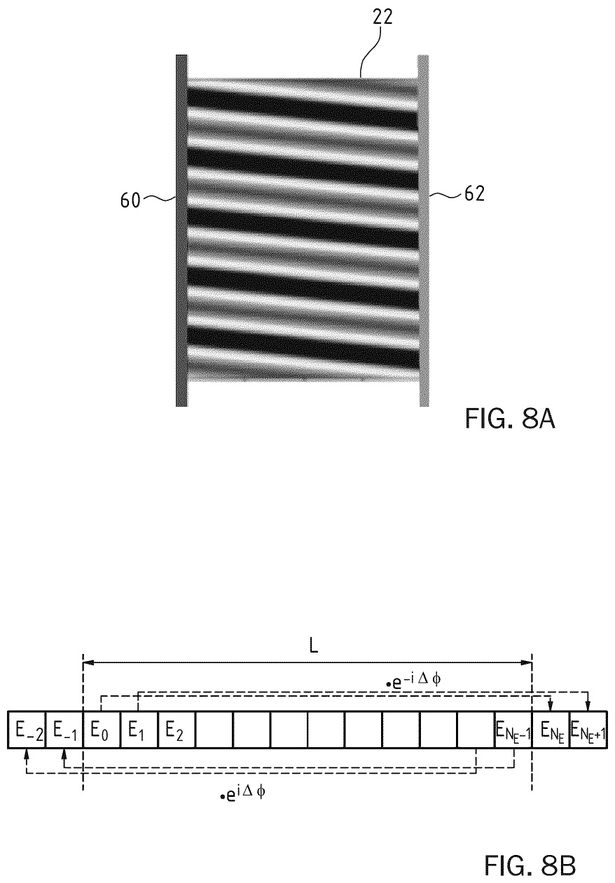

The illumination angle of the incident electromagnetic waves 22 can vary, and a representation of the electromagnetic field often has to be computed for various incident electromagnetic waves to simulate the respective near fields 20, for example in the context of partially coherent imaging simulations. The arbitrary illumination angle of the incident electromagnetic waves 22, that can be measured with respect to the normal of the absorber plane 30, however, implies that the computed electromagnetic field is not periodic but only quasi periodic according to the Floquet Theorem, i.e., periodic with an additional phase shift. FIGS. 8A and 8B illustrate the application of the Floquet Bloch theorem to opposite boundaries of the model of the photolithography mask that are orthogonal to the mask carrier plane 32. FIG. 8A illustrates a phase shift between opposite boundaries 60, 62 of the model of the photolithography mask 14 that are orthogonal to the mask carrier plane 32. The phase shift is caused by an incident electromagnetic plane wave 22 with arbitrary incident angle. The arbitrary incident angle leads to a phase shift between the left boundary 60 and the right boundary 62. To accurately model a plane wave with arbitrary incident angle, Floquet Bloch boundary conditions on at least a pair of opposite boundaries of the model of the photolithography mask that are orthogonal to the mask carrier plane are used. As illustrated in FIG. 8B, Floquet Bloch boundary conditions can be implemented by using circular padding in the convolutions at the at least one pair of opposite boundaries and multiplying the padded values with a phase shift induced by the incident angle of the electromagnetic waves. A function E is said to fulfill the ‘Floquet-Bloch boundary conditions’ or to be ‘quasi-periodic’, if it is periodic over a distance L>0 with an additional phase factor Δφ:

$$E ( x + L ) = E ( x ) {exp}^{- i Δ ϕ} .$$

If such a function is represented on a discrete grid with N_{E} gridpoints, the boundaries in a convolution can be implemented by circular padding with an additional phase factor exp^{-iΔϕ}, where the number of samples that need to be copied is N_{K}−1. N_{K}<N_{E} denotes the number of samples in the convolution Kernel K:

$$\begin{matrix}{( E * K )}_{n} = {\sum }_{m = 0}^{{N}_{k} - 1} {E}_{n - m + ⌊ {N}_{K} / 2 ⌋} {K}_{m} \\ \begin{matrix}{E}_{n} = {E}_{n + {N}_{E}} {exp}^{i Δ ϕ} & ( n < 0 )\end{matrix} \\ \begin{matrix}{E}_{n} = {E}_{n - {N}_{E}} {exp}^{- i Δ ϕ} & ( n \geq {N}_{E} )\end{matrix}\end{matrix}$$

By implementing this kind of padding in one or more layers of a neural network, for example in the output layer, allows to implement the Floquet Bloch boundary conditions correctly for these layers.

According to an aspect of the invention, the machine learning model comprises a neural network with an encoder-decoder architecture. An encoder-decoder architecture is a special case of a CNN. It can be used to map an input of a specific size to an output of a specific size, e.g., a model of a photolithography mask to a representation of an electromagnetic field. The encoder-decoder architecture involves a two-stage process where the input data is first encoded into a fixed-length numerical representation by an encoder, which is then decoded to produce an output that matches the desired format by a decoder. The encoder maps the input to a latent representation, whereas the decoder maps the latent representation to the output. The spatial resolution of the inputs of the different layers usually decreases in the encoder and increases in the decoder. The layer with the smallest spatial resolution is called “bottleneck”. The output of the bottleneck can be seen as the most abstract representation of the input in a latent space or feature space. An encoder-decoder architecture can comprise an encoder and a decoder, only an encoder or only a decoder. Due to the lower dimension of the feature space only the most relevant information is preserved in the feature space, e.g., noise or rare structures are removed. The input is, thereby, represented in an abstract way, and the abstract feature vector is then mapped to the output. Due to this structure, the training of the neural network can be carried out very efficiently, and the near fields and aerial images simulated in this way are more accurate.

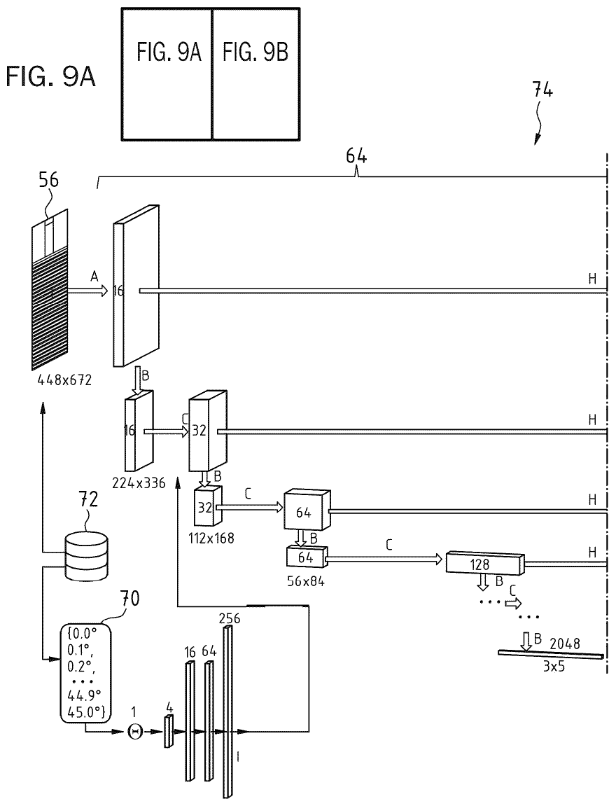

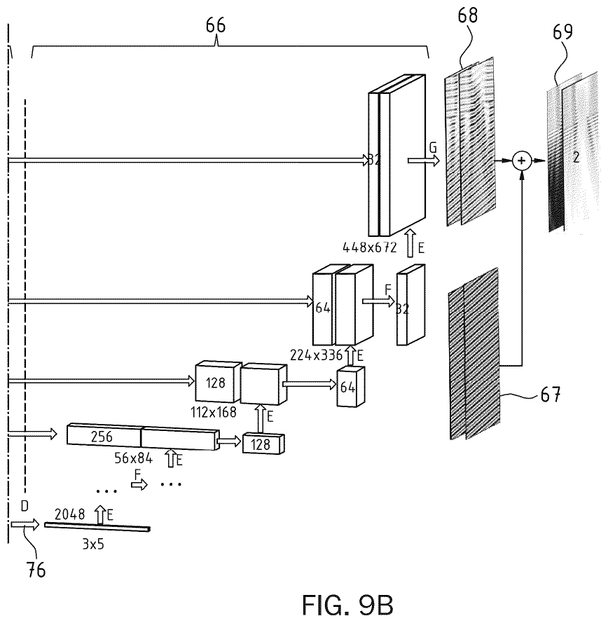

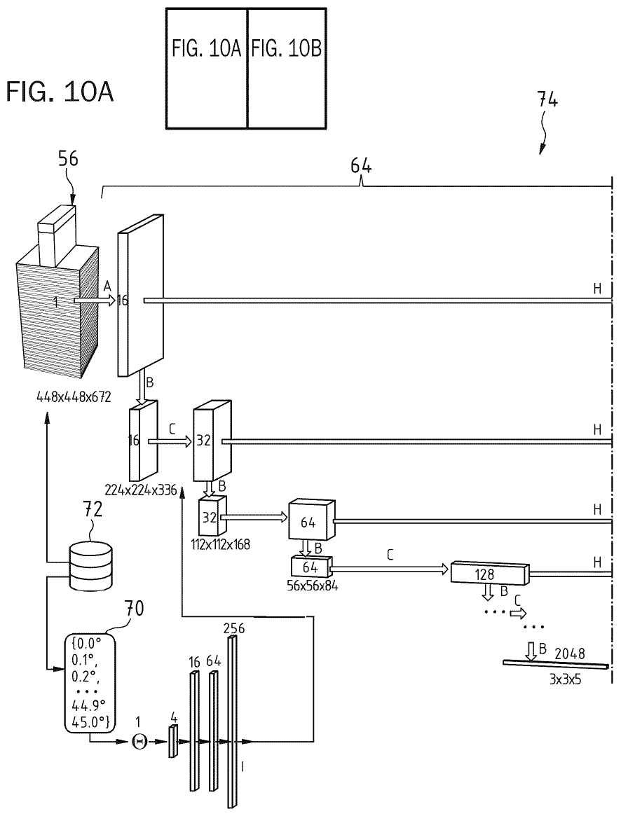

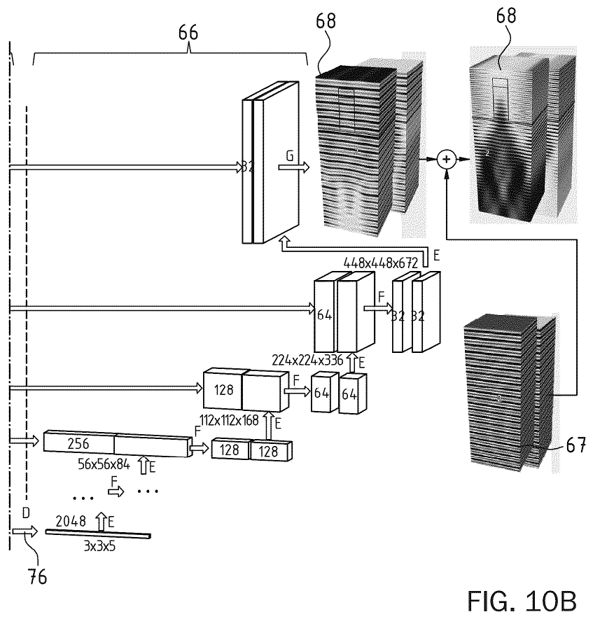

In a preferred example illustrated in FIGS. 9A, 9B, 10A, and 10B, the machine learning model comprises a neural network 74 with a U-Net architecture. In FIGS. 9A, 9B, the neural network 74 maps a model 56 of a photolithography mask 14 in the form of a cross section image 78 comprising properties of a cross section of the photolithography mask to a representation of an electromagnetic field 68 within the cross section. In case of two or more cross-section images in a model 56 of the photolithography mask, these can, for example, be concatenated to form a single image, or they can be combined as separate channels in a single input image of the machine learning model to allow for a simultaneous processing of the images belonging to the model 56. Alternatively, a machine learning model can process two or more images belonging to a model 56 sequentially, e.g., by using the images as further inputs in different layers of the machine learning model. Alternatively, multiple machine learning models can be used to process the images belonging to a model 56 sequentially, e.g., by using an image of the model 56 as input to a first machine learning model in a sequence of machine learning models, and by using the output of a preceding machine learning model and the next image of the model 56 as input to the following machine learning model in the sequence of machine learning models. In case of two or more properties within each voxel of a model 56 the model can be processed accordingly. In FIGS. 10A, 10B, the neural network 74 maps a model 56′ of a photolithography mask 14 in the form of a voxel volume 79 to a representation of an electromagnetic field 68 within the volume. The U-Net in both Figures comprises an encoder 64 that extracts relevant features from the input (the model 56, 56′ of the photolithography mask) in a latent space (bottleneck 76), and a decoder 66 that generates the output (the representation of the electromagnetic field 68 within the photolithography mask) from the extracted features in the latent space. The latent space, thus, contains a compressed representation of the essential input data. In FIGS. 9A, 9B, 10A, and 10B, the representation of the electromagnetic field 68 corresponds to the real and imaginary part of the complex scattered electric field. The complex total electric field 69 can be obtained by adding the complex incident electric field 67 to the complex scattered electric field.

A potential implementation of the transformations between the different layers of the U-Net are indicated in the following table. The abbreviation ‘c’ refers to the number of channels before and after the transformation. Other transformations can be used as well, e.g., other convolution sizes or other channel numbers.

| | Transformations in | Transformations in |
|---|---|---|
| | FIGS. 9A, 9B | FIGS. 10A, 10B |
| | (2D input) | (3D input) |
| A | 3 × 3 convolution (c: 1→16) + | 3 × 3 × 3 convolution (c: 1→16) + |
| | weight norm + | weight norm + |
| | 3 × 3 convolution (c: 16→16) | 3 × 3 × 3 convolution (c: 16→16) |
| B | 2 × 2 average pooling | 2 × 2 × 2 average pooling |
| C | 3 × 3 convolution (c→2c) + | 3 × 3 × 3 convolution (c→2c) + |
| | weight norm + | weight norm + |
| | 3 × 3 convolution (2c→2c) | 3 × 3 × 3 convolution (2c→2c) |
| D | 3 × 3 convolution (c→2c) + | 3 × 3 × 3 convolution (c→2c) + |
| | weight norm + | weight norm + |
| | 3 × 3 convolution (2c→c) | 3 × 3 × 3 convolution (2c→c) |
| E | transpose convolution with stride | transpose convolution with stride |
| | of 2 | of 2 |
| F | 3 × 3 convolution (2c→c) + | 3 × 3 × 3 convolution (2c→c) + |
| | weight norm + | weight norm + |
| | 3 × 3 convolution (c→c) | 3 × 3 × 3 convolution (c→c) |
| G | 3 × 3 convolution (c: 16→2) | 3 × 3 × 3 convolution (c: 16→2) |
| H | Skip connection | Skip connection |
| I | Input parameter neural network | Input parameter neural network |

The skip connections H are used to directly access information in the encoder 64 from the decoder 66. In this way, details contained in the input can be used by the decoder 66 instead of only relying on the information contained in the features in the latent space. The layer sizes resulting from the transformations are indicated in FIGS. 9A, 9B, 10A, and 10B. For the convolutional blocks of the U-Net, the continuously differentiable exponential linear units (CELU) activation function can, for example, be used.

In order to obtain a single machine learning model that can be used for arbitrary incident angles of the electromagnetic waves, the incident angle Θ is used as an input parameter of the machine learning model, in particular an input parameter of the neural network 74. The incident angle can be used as parameter in any of the layers of the neural network 74, e.g., in the input layer, in a layer of the encoder 64, in the bottleneck 76 or in a layer of the decoder 66. In this way, re-training of the machine learning model is not required, and a single machine learning model can be used for any incident angle Θ.

The incident angle can be encoded as an input parameter in different ways.

For example, the incident angle can be encoded as a scalar value. Alternatively, the incident angle can be encoded using an additional input channel comprising a representation of the electromagnetic field of the incident plane wave.

Alternatively, an input parameter neural network (I) can be added to the machine learning model that maps an input comprising the incident angle to a feature map as output. Thus, the incident angle is encoded as a feature map by the input parameter neural network (I). For example, in case of a machine learning model in the form of a neural network, the feature map can be used as input parameter of any of the layers of the neural network. For example, the feature map can be concatenated to any of the layers of the neural network or used as an additional channel. In case of an encoder-decoder architecture, the feature map can be used as input parameter, for example, of the bottleneck or any of the encoder layers. The input parameter neural network can, for example, be configured as a multilayer perceptron (MLP) comprising, for example, fully-connected layers as shown in FIGS. 9A, 9B, 10A, and 10B. The CELU activation function can, for example, be used for the fully connected layers of the input parameter neural network. The output of the input parameter neural network can be transformed to fit the machine learning model, e.g., to fit the size of the layer of the neural network it is concatenated to, e.g., by transforming the output to the same size as the layer it is added to. The information from the input parameter neural network is, thus, propagated through the machine learning model, e.g., through the layers of the machine learning model, in particular through the layers of the decoder. In this way, the output of the machine learning model can be controlled by selecting a scalar value.

Alternatively, the incident angle can be used as input parameter by defining an incident angle dependent convolution, i.e., an incident angle dependent kernel and bias, for convolving any of the intermediate results of the machine learning model. For example, in a case of a neural network, the incident angle dependent convolution can be applied to the output of any of the layers of the neural network, thereby introducing the incident angle as a parameter in the respective layer of the neural network. In case of an encoder-decoder neural network, the incident angle dependent convolution can be preferably applied to the bottleneck or any of the encoder layers. In an example, the incident angle dependent convolution can be trained end-to-end with the machine learning model, in particular with the neural network.

The encoded incident angle can be used as an input parameter to the machine learning model, for example in case of a neural network, by adding it to any of the layers of the neural network, e.g., as a scalar value, as an additional channel, by concatenation, or by applying an incident angle dependent convolution to any of the layers of the neural network.

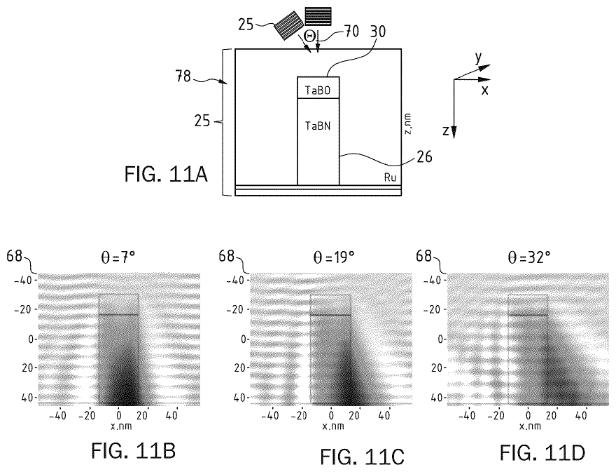

FIGS. 11A to 11D illustrate a single neural network 74 that generates representations of electromagnetic fields for arbitrary incident angles Θ of the generated electromagnetic waves 22 on the photolithography mask 14. The incident angle Θ can, for example, be measured with respect to the normal of the surface of the absorber plane 30. Values for Θ are considered within the range [0°, 45° ], but other ranges can be considered as well. FIG. 11A shows a cross section image 78 of the absorber section 25 containing different absorber materials Tantalum Boride Oxide (TaBO) and Tantalum Boron Nitride (TaBN) within a carrier made of Ruthenium (Ru). The cross section image 78 contains 224×256 pixels corresponding to a physical size of 112×128 nm. The physical width of the absorber section 25 is 27 nm. A single neural network 74 is trained to map a cross section image 78 to a corresponding representation of an electromagnetic field 68 for different incident angles Θ. The incident angle Θ is indicated as a parameter of the neural network 74 as shown in FIGS. 9A, 9B, 10A, and 10B, in particular as a parameter of the second convolutional layer. FIGS. 11B, 11C and 11D show the simulated representations of the electromagnetic fields 68 in the form of the amplitude of the complex total electric field within the region of the photolithography mask that corresponds to the cross section image 78 in FIG. 11A for different incident angles Θ=7°, Θ=19° and Θ=32°.

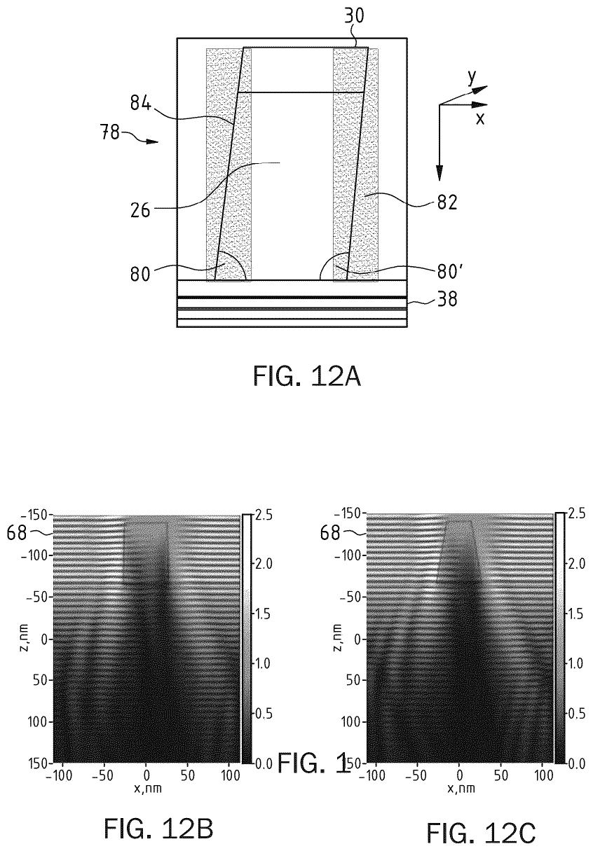

The absorber structures 26 within the absorber section 25 vary not only in material but also in shape. FIGS. 12A-12C illustrate the variation of the shape of the absorber structures 26 within the absorber section 25 of the photolithography mask 14 and the simulated representations of the electromagnetic fields 68. In FIG. 12A, the absorber structures 26 within the absorber section 25 vary in width and side wall angles 80, 80′. The side wall angles 80, 80′ denote the angles of the side walls 84 of the absorber structures 26 with respect to the absorber plane 30. The side wall angles 80, 80′ can both vary within a range of [79.66°, 100.66°] degrees, but other ranges are possible as well. The width of the absorber structures 26 can vary within a range of [27 nm, 54 nm]. Thus, the side walls 84 can vary within the side wall variation area 82. For example, slanted absorber structures or trapezoidal absorber structures can be represented in this way. By using training data comprising models of photolithography masks containing absorber sections 25 with absorber structures 26 of varying shapes, the neural network 74 can be trained to generate representations of electromagnetic fields 68 for different absorber structure shapes. The training data can be generated automatically by defining ranges for the side wall angles and the width of the absorber structures 26, randomly selecting values from these ranges and creating the corresponding cross section image as training sample. The size of the cross section image 78 that is used as input to the machine learning model is 448×672 pixels corresponding to a physical size of 224×336 nm. FIGS. 12B and 12C show representations of electromagnetic fields 68 in the form of the amplitude of the complex total electric field that are simulated for different shapes of the absorber structures 26 for an incident angle Θ=6° of the electromagnetic waves.

In order to accurately model shape variations at nm scale, the spatial resolution of the model of the photolithography mask has to be very fine such that pixel boundaries coincide with structure boundaries. However, large spatial resolutions lead to very large numbers of pixels that have to be processed by the neural network, thereby strongly increasing the required memory and computation time. The invention describes different ways of reducing the spatial resolution of the photolithography mask to reduce memory and computation time requirements.

In order to reduce the required memory and computation time, the model of the photolithography mask can comprise an image containing at least one image element that corresponds to a location in the photolithography mask containing two or more different material property values for the same material property. Thus, single image elements can contain multiple material property values. In this way, the boundaries of the image elements do not have to coincide with the structure or material boundaries in the photolithography mask. Therefore, the spatial resolution of the image is independent of the size of the structures within the photolithography mask. Thus, coarse spatial resolutions can be used and still accurate results achieved, thereby saving memory and computation time.

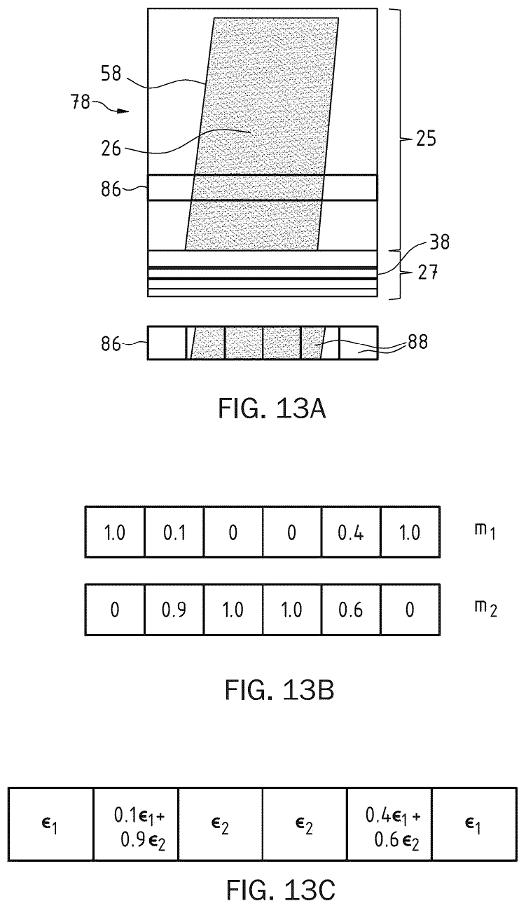

FIGS. 13A-13C illustrate models of a photolithography mask using at least one image element 88 that corresponds to a location in the photolithography mask 14 containing two or more different material property values for the same material property. FIG. 13A shows a model of an EUV photolithography mask in the form of a cross section image 78 comprising the absorber section 25 including an absorber structure 26 and a part of the mask carrier section 27 containing several layers of the multilayer 38. A line 86 of the cross section image 78 consists of a number of image elements 88. Two of the image elements 88 within the line 86 contain two different materials and, thus, two different material property values for the same material property. FIG. 13B shows a potential configuration of the cross section image 78 within the line 86 by using two channels in the cross section image. The first channel comprises the proportion of the area of the image element belonging to a first material m₁, and the second channel comprises the proportion of the area of the image element belonging to a second material m₂. In case the image elements 88 contain refractive indices in the form of complex numbers, the cross section image can, for example, contain six channels, two channels for the refractive indices of the first material, two channels for the refractive indices of the second material, and two channels indicating the proportion of the area belonging to each of the materials.

FIG. 13C shows a potential configuration of the cross section image 78 within the line 86 by using an effective material property. The effective material property value within an image element that contains two or more different material property values can, for example, be computed using a mean value, in particular a harmonic or an arithmetic mean value, of the material property values weighted by the proportion of the area or volume of the image element containing the material. Material properties include, for example, the relative electric permittivity ϵ(r, ω), the magnetic permeability or the refractive index, etc. Assuming vacuum permeability for simplicity, the dielectric constant or relative electric permittivity ϵ(r, ω) of a material is related to the refractive index n(r, ω) of the material by

ϵ(r,ω)=n(r,ω)².

Let Sᵢ indicate the proportion of the i-th material within an image element of area or volume S comprising n materials, and let ϵᵢ indicate the relative electric permittivity of the i-th material. Then the effective relative electric permittivity value within the image element can, for example, be computed using the arithmetic mean as follows

$${∈}^{eff} = {\sum }_{i = 1}^{n} \frac{{S}_{i}}{S} {∈}_{i} , s . t . {\sum }_{i = 1}^{n} \frac{{S}_{i}}{S} = 1 .$$

The arithmetic mean for two materials with electric permittivity ϵ₁ and ϵ₂ is shown in FIG. 13C.

Alternatively, the harmonic mean can be used to compute the effective relative electric permittivity value

$${∈}^{eff} = \frac{S}{{\sum }_{i = 1}^{n} \frac{{S}_{i}}{{∈}_{i}}} , \qquad s . t . {\sum }_{i = 1}^{n} \frac{{S}_{i}}{S} = 1.$$

Instead of the relative electric permittivity ϵ, other material properties can be used to compute the corresponding effective material property, for example, the effective magnetic permeability or the effective refractive indices of the materials, etc.

The computation of an effective material property for Maxwell's equations is described, for example, in “A Conformal Finite Difference Time Domain Technique for Modeling Curved Dielectric Surfaces, Wenhua Yu, Raj Mittra, IEEE Microwave and Wireless Components Letters, Vol. 11, No. 1, 2001”, in “A Conformal Finite-Difference Time-Domain Technique for Modeling Cylindrical Dielectric Resonators, Supriyo Dey, Raj Mittra, IEEE Transactions on Microwave Theory and Techniques, Vol. 47, No. 9, 1999” and in “FDTD Analysis of Dielectric Resonators with Curved Surfaces, Noriaki Kaneda, Bijan Houshmand, Tatsuo Itoh, IEEE Transactions on Microwave Theory and Techniques, Vol. 45, No. 9, 1997”. The effective material property value can be computed analogously for three or more different materials contained in an image element.

In order to reduce the number of image elements and, thus, the computation time of the method, image elements of differing physical sizes can be used. In an example, the model of the photolithography mask comprises an image containing image elements 88, in particular pixels or voxels, wherein the physical sizes of image elements 88 differ. The image can be a 2D image or a 3D image. The physical sizes of image elements 88 differ if the physical dimensions of the sections of the photolithography mask, that are represented by the image elements, differ. In this way, the physical sizes of image elements can be adapted to coincide with the boundaries of the structures within the photolithography mask. e.g., with the boundaries of the layers within the multilayer or with the boundaries of the absorber structures within the absorber section. Thus, the image elements only contain a single material property value and, thus, accurately represent the different materials of the absorber section 25 or the multilayer 38 within the photolithography mask. In this way, the accuracy of the simulated near fields and aerial images is improved. At the same time, the number of image elements and, thus, the computation time of the method is reduced. Even at nm scale, a coarse spatial resolution can be used for the model of the photolithography mask.

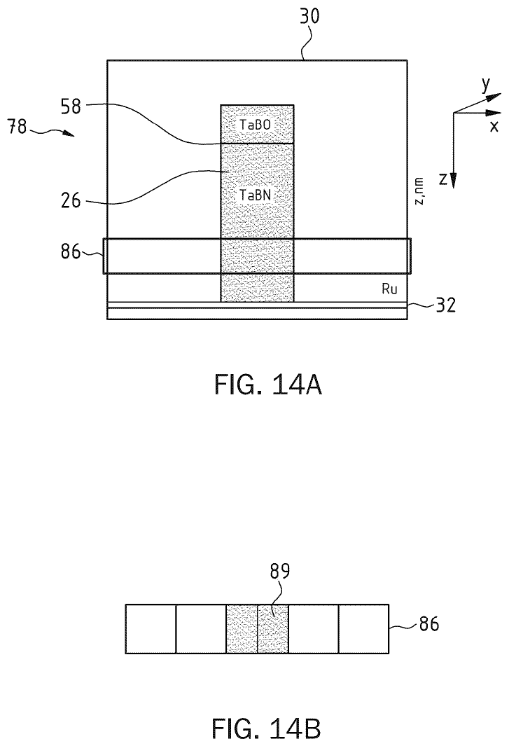

FIGS. 14A and 14B illustrate the use of image elements 88 of different physical sizes that coincide with the boundaries of the absorber structures 26 within a model of a photolithography mask. In this way, the spatial resolution of the model 56, 56′ of the photolithography mask 14 can be reduced. FIG. 14A shows a cross section image 78 of an absorber section 25 of a model of a photolithography mask containing an absorber structure 26. The cross section image 78 contains 224×256 pixels corresponding to a physical size of 112×128 nm. FIG. 14B illustrates the physical sizes of image elements 88 of a line 86 of the cross section image 78. The physical sizes of the image elements 88 differ. In this way, the image elements 88 in the image in form of the cross section image 78 can be configured such that the boundaries of the image elements 88 coincide with the boundaries 58 of the structures in the model of the photolithography mask, e.g., with the boundaries 58 of the absorber structure 26.

In case of EUV photolithography masks, the spatial resolution of the model of the photolithography mask can also be reduced. In an EUV photolithography mask the mask carrier comprises a multilayer 38 in the form of a stack of optical thin films for reflecting the electromagnetic waves. FIGS. 15A and 15B illustrate the use of image elements 88 of different physical sizes that coincide with the boundaries 58 of the layers of the multilayer 38 in a model of an EUV photolithography mask. In this way, the spatial resolution of the model of the EUV photolithography mask can be reduced and, thus, the required memory and computation time. The model of the photolithography mask in FIG. 15A comprises a cross section image 78 containing image elements 88 in the form of pixels. For each pixel, its coordinates, its physical size and/or material properties such as complex refractive indices, electric permittivities, magnetic permeabilities, or derived representations are provided. FIG. 15B shows an enlarged section of the multilayer 38 containing different layers of different thicknesses in z-direction. To prevent using a large amount of image elements 88 to accurately model the layer boundaries, the physical sizes of the pixels in at least two different layers differ. For example, the thickness of a first layer 90 is larger than the thickness of a second layer 92. Both layers can, for example, be modeled using the same amount of pixels in z-direction by adapting the physical size of the pixels within the two layers. The physical size of the image elements 88 within the first layer 90 can, for example, be larger in z-direction than the physical size of the image elements 88 within the second layer 92. In fact, both layers can be represented by a single line of image elements 88 in the model of the photolithography mask as shown in FIG. 15B. Alternatively, different numbers of lines of image elements 88 can be used to model the different layers. The physical thicknesses of the image elements 88 within the lines in a layer can be configured such that the physical boundaries of the layers in the multilayer 38 coincide with boundaries 58 of the image elements 88.

Different physical sizes of the image elements can be implemented by using an approximation scheme of derivatives of the representation of the electromagnetic field that takes into account the physical sizes and distances of the image elements, in particular approximation schemes relying on finite differences or finite elements, as described below in the context of the training of the machine learning model.

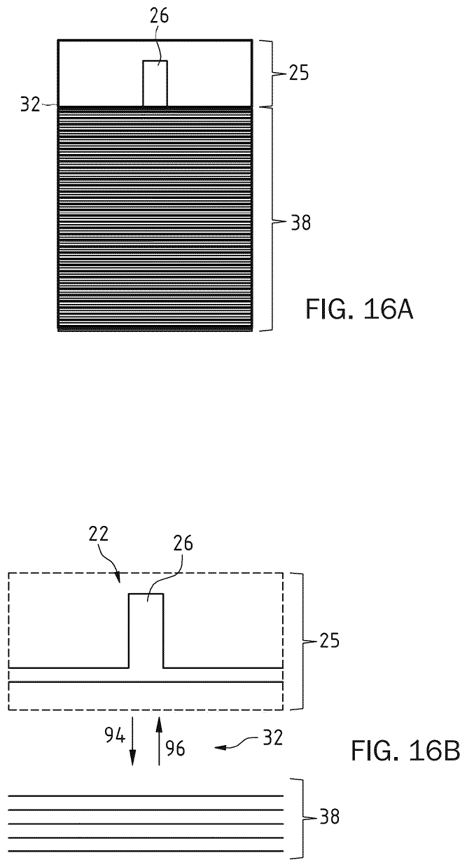

According to a preferred embodiment of the invention illustrated in FIGS. 16A and 16B, the machine learning model simulates the propagation of the incident electromagnetic waves 22 within the absorber section 25 of an EUV photolithography mask, and the propagation of the electromagnetic waves within the multilayer 38 is computed analytically or with a numerical method not involving machine learning. The propagation of the electromagnetic waves within the multilayer 38 analytically or with a numerical method not involving machine learning is computed by using a boundary condition that describes the reflection of the electromagnetic waves at a plane parallel to the mask carrier plane 32 within the mask carrier section 27, preferably at the mask carrier plane 32. The mask carrier plane 32 is the boundary between the absorber section 25 and the mask carrier section 27. Instead of simulating the propagation of the outgoing electromagnetic waves 94 leaving the absorber section 25 throughout the different layers of the multilayer 38, the reflected electromagnetic waves 96 that are reflected by the multilayer 38 are analytically or with a numerical method not involving machine learning computed and used as boundary condition in the machine learning model. Since the machine learning model does not simulate the propagation of the electromagnetic waves within the mask carrier section, the memory requirements and computation time are strongly reduced.

In an example, the boundary condition comprises an absorbing boundary condition, in particular a perfectly matched layer boundary condition, and a reflection term representing the electromagnetic waves after reflection at the multilayer 38. A perfectly matched layer boundary condition (PML) is an artificial absorbing layer for wave equations, commonly used to truncate computational regions in numerical methods to simulate problems with open boundaries, especially in the finite-difference time-domain (FDTD) and finite element (FE) methods. The key property of a PML that distinguishes it from an ordinary absorbing material is that it is designed so that waves incident upon the PML from a non-PML medium do not reflect at the interface—this property allows the PML to strongly absorb outgoing waves from the interior of a computational region without reflecting them back into the interior.

PML boundary conditions for Maxwell's Equations have originally been introduced in “Berenger, J. P. (1994) A Perfectly Matched Layer for the Absorption of Electromagnetic Waves, Journal of Computational Physics, 114, 185-200. http://dx.doi.org/10.1006/jcph.1994.1159” In order to apply PML boundary conditions to model the absorption of the electromagnetic waves at the multilayer, a so-called stretched-coordinate PML is used, where the derivative operators in the Maxwell's or Helmholtz equation are suitably modified by a complex-valued coordinate transform, as described in detail in “MaxwellNet: Physics-driven deep neural network training based on Maxwell's equations, Joowon Lim, Demetri Psaltis; APL Photonics 1 Jan. 2022; 7 (1): 011301, section 3 of the Supplementary Material and the references therein”.

In order to model the reflected electromagnetic waves 96, the reflection of the outgoing electromagnetic waves 94 by the multilayer 38 at a plane parallel to the mask carrier plane 32 within the mask carrier section 27 is computed analytically or with a numerical method not involving machine learning. For example, the reflection of the outgoing electromagnetic waves 94 by the multilayer 38 could be computed as follows: in a first step, the inferred (total) electric field at the mask carrier plane 32 is decomposed in its Fourier Modes. In a second step, for each Fourier mode, the reflected electromagnetic field can be computed using, for example, the transfer matrix method (described in Section 2.2 of the article “Domain Decomposition Method for Maxwell's Equations: Scattering off Periodic Structures, Achim Schsdle, Lin Zschiedrich, Sven Burger, Roland Klose, Frank Schmidt, in arXiv:math/0602179v1”) or the precomputed analytic reflection coefficients described in the article “Optical properties of a thin-film stack illuminated by a focused field, S. Kim, Y. Kim, I. Park, Journal of the Optical Society of America A, Vol. 17, No. 8, 2000, equations 33 to 41”. In a third step, the superposition of the reflected Fourier modes yields the reflected electromagnetic waves 96 which are used as an excitation term for the absorber section.

In a preferred example, these three (nonlinear) steps are implemented in the loss-function in a way, such that the derivatives can be automatically computed and used for backpropagation during the training of the machine learning model. In this way, also non-linear reflection terms can be easily integrated into the loss function. In contrast, related domain decomposition approaches employed in classical finite element methods, for example Section 5 of the article by Achim Schsdle et al. mentioned above, uses time-consuming Schwarz iterations between different domains to match the electromagnetic fields at the boundary due to the non-linearity of the reflection term.

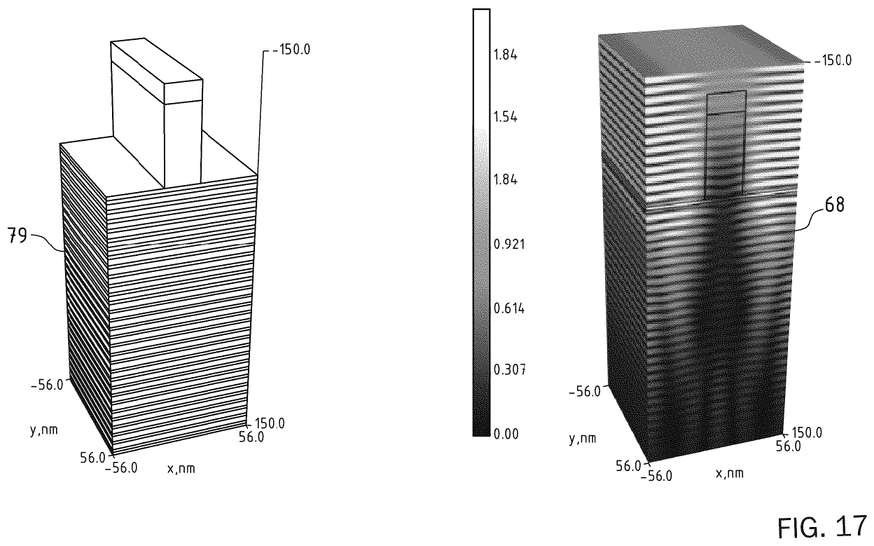

FIG. 17 illustrates an exemplary representation of an electromagnetic field 68 in the form of an amplitude of the total complex electric field (on the right) that is simulated using a model of a photolithography mask in the form of a voxel volume 79 comprising properties of a section of the photolithography mask, in particular refractive indices of materials within the section of the photolithography mask (on the left). The voxel volume 79 is used as input to the trained machine learning model, for example the U-Net in FIGS. 10A, 10B. The resulting representation of the electromagnetic field 68 generated by the incident electromagnetic waves on the photolithography mask is highly accurate, since it is consistent with the underlying physical principles that are applied during training of the machine learning model. From the simulated representation of the electromagnetic field a near field can be obtained in a near field plane, and from the near field an aerial image in the wafer plane can be obtained by simulating an imaging process of a photolithography system or optical metrology system within the projection section extending between the near field plane and the wafer plane. The required computation time for simulating the electromagnetic field within the photolithography mask during inference is several orders of magnitude faster than simulating the electromagnetic field using a rigorous simulation method such as RCWA.

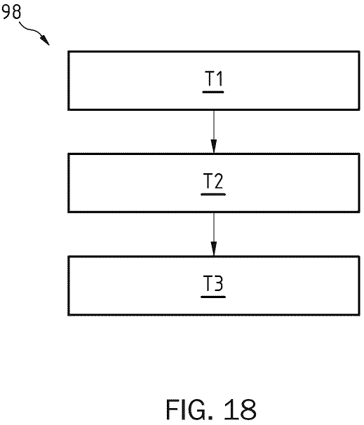

FIG. 18 illustrates a flow chart of a computer implemented method 98 for training a machine learning model for simulating the propagation of electromagnetic waves through a model of a photolithography mask as used in any of the embodiments above. The method comprises: generating models of photolithography masks and, optionally, incident angles of the electromagnetic waves incident on the photolithography masks, as training data, wherein each model of a photolithography mask comprises a mask carrier and a grating, the grating comprising absorber structures and non-absorber structures forming a pattern on at least a portion of the mask carrier, and wherein each model of a photolithography mask comprises an absorber section extending between an absorber plane and a mask carrier plane of the photolithography mask and a mask carrier section extending between the mask carrier plane and a base plane of the photolithography mask in a step T1; iteratively presenting one or more models of photolithography masks and, optionally, incident angles, from the training data to the machine learning model in a step T2; and evaluating the loss function and modifying the parameters, in particular the weights, of the machine learning model in a step T3.

The incident angle Θ can be used as additional input parameter to the machine learning model as described above. Alternatively, the machine learning model can include different sub-machine learning models for different incident angles Θ. The training data sample is then used as input to the machine learning model whose incident angle Θ is closest to the incident angle of the training data sample.

The training data 72 for training the neural network 74 in FIG. 9A, 9B, or 10A, 10B contains, for example:
a model 56, 56′ of a photolithography mask 14, e.g., a 2D cross section image or a voxel volume, with two channels comprising refractive indices in the form of complex numbers,
optionally, an incident angle of the incident electromagnetic waves, e.g., within the range [0, 45° ].

The models 56, 56′ of the photolithography masks can, for example, be generated according to specific rules defining the structure of photolithography masks, e.g., by randomly selecting parameters within predefined ranges as illustrated in FIG. 12A. The parameters can, for example, define material properties, locations, dimensions and side wall angles of absorber structures in the absorber section 25 and/or materials, locations and dimensions of layers within a multilayer in the mask carrier section 27.

In a preferred embodiment, the loss function comprises one or more partial differential equations (PDEs) describing properties of the representation of the electromagnetic field within the photolithography mask. In a preferred example, the one or more partial differential equations are derived from Maxwell's equations in (1) or from the Helmholtz equation in (3). During a training step, one or more training samples are presented as input to the machine learning model. The machine learning model simulates the electromagnetic field within the photolithography mask. For the simulated electromagnetic field the one or more PDEs, e.g., Maxwell's equation in (1) or the Helmholtz equation in (3), are evaluated and the residual computed. In case of a perfect simulation, the evaluation of the PDEs should yield a residual of 0. The residual can, thus, be used to modify the parameters of the machine learning model, e.g., the weights of the different layers of the neural network. To modify the parameters, learning algorithms are used, for example a backpropagation algorithm or one of its derivatives. As the loss function contains the one or more PDEs, the learned mapping of a model of a photolithography mask to a representation of an electromagnetic field generated by incident electromagnetic waves on the photolithography mask is consistent with the underlying physical principals. In addition, no time-consuming rigorous simulation of electromagnetic fields corresponding to the models of the photolithography masks is required to generate the training data.

Since the PDEs in the loss function contain derivatives of the electromagnetic field that is given in form of a 2D or 3D image, these derivatives have to be evaluated on a discretized grid of the model of the photolithography mask. To evaluate derivatives on a discretized grid, approximation schemes such as finite differences or finite elements can be used. The circular padding for implementing Floquet-Bloch boundary conditions as described above can be used here.

According to an aspect of the invention, the loss function is evaluated using an approximation scheme of derivatives of the representation of the electromagnetic field that takes into account the physical sizes of the image elements, in particular approximation schemes relying on finite differences or finite elements. In the context of Maxwell's equations, approximation schemes for uniform grids using finite differences can be used as described, for example, in the Supplementary Material, Section 2, of “MaxwellNet: Physics-driven deep neural network training based on Maxwell's equations, Joowon Lim, Demetri Psaltis; APL Photonics 1 Jan. 2022; 7 (1): 011301.” In case of finite element methods, approximation schemes described in “Finite Element Methods for Maxwell's Equations, Peter Monk, Oxford Science Publications, 2003”.

In the following, an example for a potential loss function is described. Starting out from the Helmholtz equation in (3)

$$Δ E ( r , ω ) + \frac{{ω}^{2}}{{c}^{2}} ∈ ( r , ω ) E ( r , ω ) = 0$$

the electric field

$$E ( r , ω ) = {E}_{i n c} ( r , ω ) + {E}_{sc} ( r , ω ) .$$

is decomposed into an incident electric field E_{inc} and a scattered electric field E_{sc}. E(r, ω)=E_{inc}(r, ω)+E_{sc}(r, ω). The incident electric field E_{inc}(r, ω) fulfills the Helmholtz equation for the background material permittivity ϵ_{b}, such that

$$Δ {E}_{i n c} ( r , ω ) = - \frac{{ω}^{2}}{{c}^{2}} {∈}_{b} {E}_{inc} ( r , ω ) . \qquad ( 4 )$$

$$This yields$$

$$Δ {E}_{sc} ( r , ω ) - \frac{{ω}^{2}}{{c}^{2}} {∈}_{b} {E}_{inc} ( r , ω ) + \frac{{ω}^{2}}{{c}^{2}} ∈ ( r , ω ) E ( r , ω ) = 0.$$

The so-called stretched coordinate PML boundary conditions at the boundaries parallel to the mask carrier plane are implemented by replacing the Laplace operator Δ by Δₛ, which involves the complex-valued coordinate transform, as described in detail in the supplementary material and the corresponding references in “MaxwellNet: Physics-driven deep neural network training based on Maxwell's equations, Joowon Lim, Demetri Psaltis; APL Photonics 1 Jan. 2022; 7 (1): 011301”. The loss function can then be defined as the mean-squared residual of equation (4) evaluated at each pixel within the computational domain:

$$L = \frac{1}{N} {\sum }_{j = 1}^{N} {‖ {Δ}_{s} {E}_{s c} ( {r}_{j} , ω ) - \frac{{ω}^{2}}{{c}^{2}} {∈}_{b} {E}_{inc} ( {r}_{j} , ω ) + \frac{{ω}^{2}}{{c}^{2}} ∈ ( {r}_{j} , ω ) E ( {r}_{j} , ω ) ‖}^{2} \qquad ( 5 )$$

where rⱼ=1, . . . , N denotes the coordinates of the N pixels. The derivatives are approximated by a higher order finite difference approximation, where the modified circular padding described above is employed to suitably take into account the Floquet-Bloch boundary conditions for oblique incidence angles. To implement the loss-function within a real-valued machine learning framework, one can further separate the complex electric field components E= [symbol] [E]+i [symbol] [E] and material parameters ϵ= [symbol] [ϵ]+i [symbol] [ϵ] into their real part [symbol] [·] and imaginary part [symbol] [·] and compute the different contributions to the residual in (4) separately. In particular, this leads to the alternative (real-valued) representation of the loss-function in (5)

$$\begin{matrix}{L}_{ℛ} ( r , ω ) = {Δ}_{s} ℛ [ {E}_{s c} ( r , ω ) ] - \frac{{ω}^{2}}{{c}^{2}} {∈}_{b} ℛ [ {E}_{i n c} ( r , ω ) ] + \frac{{ω}^{2}}{{c}^{2}} ( ℛ [ ∈ ( r , ω ) ] ℛ [ E ( r , ω ) ] - 𝒥 [ ∈ ( r , ω ) ] 𝒥 [ E ( r , ω ) ] ) \\ {L}_{𝒥} ( r , ω ) = {Δ}_{s} 𝒥 [ {E}_{s c} ( r , ω ) ] - \frac{{ω}^{2}}{{c}^{2}} {∈}_{b} 𝒥 [ {E}_{i n c} ( r , ω ) ] + \frac{{ω}^{2}}{{c}^{2}} ( 𝒥 [ ∈ ( r , ω ) ] ℛ [ E ( r , ω ) ] + 𝒥 [ ∈ ( r , ω ) ] ℛ [ E ( r , ω ) ] ) \\ L = \frac{1}{N} {\sum }_{j = 1}^{N} {‖ {L}_{ℛ} ( {r}_{j} , ω ) ‖}^{2} + {‖ {L}_{𝒥} ( {r}_{j} , ω ) ‖}^{2}\end{matrix}$$

Different variations of this loss function are possible, e.g., different norms can be used instead of the mean squared error in the loss function, the full Maxwell's equations in (1) can be used instead of the Helmholtz equation in (3), the residual can be evaluated at other coordinates (e.g., only at a subset of the pixels), etc.

In case of non-uniform grids as described above in the context of image elements with varying physical sizes, approximation schemes for finite differences can be used as, for example, described in “A Convergence Analysis of Yee's Scheme on Nonuniform Grids, Peter Monk, Endre Süli, SIAM Journal on Numerical Analysis, Vol. 31, No. 2, pp. 393-412, 1994”.

By using finite differences, for example, the physical size of the image elements can be used in the denominator of the first order approximation

$${f}^{′} ( x ) \approx \frac{f ( x + a ) - f ( x )}{p ( x + a ) - p ( x )} ,$$

where p(x+a)−p(x) refers to the physical distance between x+a and x. In an example, a Yee-grid-based discretization scheme can be used to approximate the derivatives. Second-order spatial derivatives can be approximated using higher order approximation schemes, e.g., second order or fourth order finite differences.

In an example concerning EUV photolithography masks as illustrated in FIGS. 16A and 16B, the machine learning model simulates the propagation of electromagnetic waves within an absorber section of a photolithography mask, and the loss function computes the propagation of the electromagnetic waves within the multilayer analytically as described with respect to FIGS. 16A and 16B above. In particular, the loss function comprises a boundary condition that describes the reflection of the electromagnetic waves at a plane parallel to the mask carrier plane within the mask carrier section. To this end, the loss function can comprise an absorbing boundary condition, in particular a perfectly matched layer (PML) boundary condition, and a reflection term that analytically or with a different numerical method not involving machine learning, e.g., the transfer matrix method, computes the electromagnetic waves reflected by the multilayer at a plane parallel to the mask carrier plane within the mask carrier section as described above with respect to FIGS. 16A and 16B.

For training of the neural network, physical and mathematical parameters have to be selected, e.g., the wavelength of the incident electromagnetic waves, polarization, the boundary condition, the thickness of the perfectly matched layer in case a PML boundary condition is used, specific approximation schemes for the derivatives in the PDEs, etc. Furthermore, hyperparameters of the machine learning model, e.g., of the U-Net in FIG. 9A, 9B or 10A, 10B, have to be selected. In case of a neural network, these hyperparameters comprise, among others, the depth of the neural network, the filter size of the convolutional layers, the number of input and output channels in each step, the order and number of convolutions, normalizations and other layers, the normalization, the upsampling scheme, the learning rate, the learning rate decay, the number of epochs, the batch sizes, the optimizer, etc. The hyperparameters of the machine learning model can be selected automatically using hyperparameter optimization techniques known to a person skilled in the art. These techniques can be used to automatically find optimal hyperparameter combinations for the given task.

The training process of the U-Net can, for example, be carried out as follows: in a first step, training and validation datasets are generated comprising models of photolithography masks in the form of material distributions comprising refractive indices of the different materials within the photolithography masks. The refractive indices can be represented by complex numbers. Alternatively, the training and validation dataset can be generated randomly by applying rules that define structures of photolithography masks, e.g., ranges for the width, the side wall angles and the distances of absorber structures, ranges for the number and thicknesses of the layers within the multilayers, etc. In addition, each training sample contains an incident angle Θ of the incident electromagnetic waves. Within a training epoch, a batch size of training samples is presented to the U-Net as input, and the electromagnetic fields are computed by the U-Net in a forward pass. The computed one or more electromagnetic fields are padded depending on the selected boundary condition, e.g., using zero-padding in case of PML boundary conditions or Floquet-Bloch circular padding for quasi-periodic boundary conditions. For example, a Yee-grid-based discretization scheme can then be used to approximate first and second order derivatives. To this end, also finite difference approximation schemes of higher orders, e.g., of second or fourth order, can be employed. After discretization the derivatives are unpadded to the original size, and the physics-based loss function is evaluated. To this end, the original Helmholtz PDE in (3) is modified in two ways: firstly, the total electric field E=E_{inc}+E_{sc} is decomposed into an incident electric field E_{inc} and a scattered electric field E_{sc}. Secondly, the PDE is decomposed into two parts for the real and imaginary parts, in order to support the material distribution in form of the complex refractive indices within a real-valued neural network architecture. The physics-based loss function is then evaluated by computing the residual of the PDE. Finally, backpropagation or a variant thereof is used to modify the weights of the U-Net based on the value of the loss function.

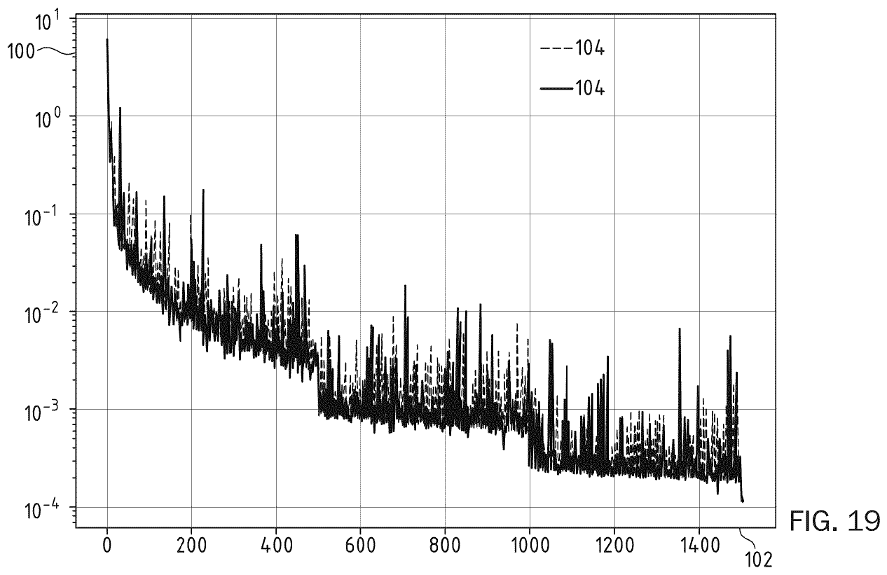

FIG. 19 illustrates the training progress for the training of the U-Net shown in FIGS. 9A, 9B according to the previously described training process. The training of the U-Net was carried out using the following parameters: the depth of the U-Net was set to 8, the filter size of the convolutional layers was set to 16, the learning rate was set to 0.0001, the learning rate decay was set to 0.5 every 1000 epochs, the batch size was selected as 4, the CELU activation function was used for the convolutional blocks of the U-Net and for the fully connected layers of the input parameter neural network, and the Adam optimizer with an initial learning rate within [0.0001, 0,0005] was used. FIG. 19 shows the number of epochs on the horizontal axis 102 and the value of the loss function on the vertical axis 100 for the training dataset 104 and for the validation dataset 106 (dashed lines). The graph shows that the value of the loss function is reduced quickly for both the training data and the validation data and converges to a loss function value close to 0 within 1500 epochs.

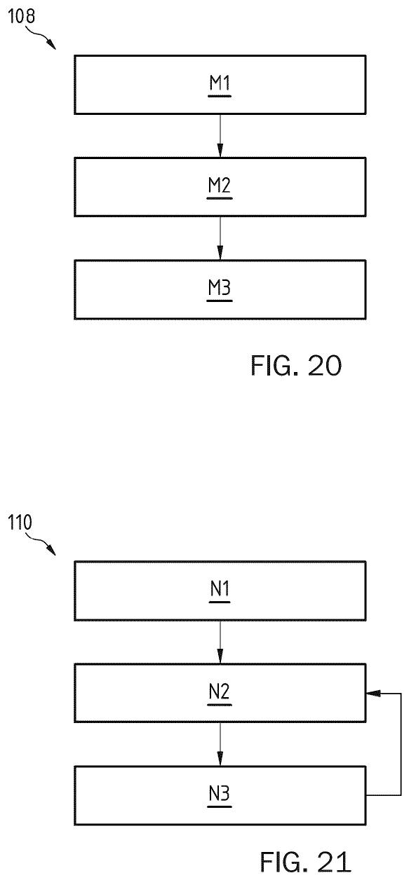

FIG. 20 illustrates a computer implemented method 108 for detecting defects in a photolithography mask according to an embodiment of the invention, the computer implemented method 108 comprising: obtaining an aerial image of the photolithography mask in a step M1; simulating an aerial image of a model of the photolithography mask using a computer implemented method 54 for simulating an aerial image of a model of a photolithography mask according to any of the embodiments described above in a step M2; and detecting defects in the photolithography mask by comparing the obtained aerial image to the simulated aerial image in a step M3. Deviations of the obtained aerial image from the simulated aerial image can, for example, be found by computing a difference image. A threshold can be applied to the difference image to detect defects. Alternatively, defect detection methods can be applied to the obtained aerial image and the simulated aerial image or to the difference image, e.g., template matching methods that use predefined or learned templates of defects to detect defects, or machine learning models that are trained to detect defects using the obtained and simulated aerial images as input or the difference image.

FIG. 21 illustrates a computer implemented method 110 for assessing the relevance of defects in a photolithography mask according to an embodiment of the invention, the computer implemented method 110 comprising: providing a charged particle beam image of the photolithography mask comprising one or more defects in step N1 (the particle beam image is preferably of the same size as the simulated aerial image in step N2); simulating an aerial image of a model of the photolithography mask using a computer implemented method 54 for simulating an aerial image of a model of a photolithography mask according to any of the embodiments described above, wherein the charged particle beam image is used as a model of the photolithography mask, in a step N2; assessing the relevance of the one or more defects in the photolithography mask using the simulated aerial image in a step N3. A defect is assessed as relevant if it will print on the wafer during the printing process. In contrast, defects that will not print on the wafer are assessed as not relevant. The charged particle beam image can be a 2D image or a 3D image. In case of a 2D image, the image can show a cross-section image in the X-Y plane or in the X-Z plane or in the Y-Z plane, e.g. a top view image in the X-Y plane, as a model of the photolithography mask. In case of a 3D image, the charged particle beam image can show a voxel volume as model of the photolithography mask. The charged particle beam image can be processed to obtain a model of the photolithography mask, e.g., a threshold can be applied to discriminate the structures of the photolithography mask from the background. The charged particle beam image is obtained by a charged particle beam device, for example, a Helium ion microscope (HIM), a cross-beam device including focused ion beam (FIB) and scanning electron microscope (SEM) or any charged particle imaging device. The assessment step N3 can comprise the comparison of the simulated aerial image to the charged particle beam image. For example, the one or more locations of the one or more defects in the charged particle beam image can be compared to the corresponding one or more locations in the simulated aerial image. If a defect is not visible in the simulated aerial image it can be concluded that it does not print on the wafer and is, thus, not relevant. If a defect is visible in the simulated aerial image it can be concluded that it does print on the wafer and, thus, is relevant. The simulated aerial image can also be compared to a reference image, e.g., a simulated or acquired aerial image of the photolithography mask to assess the relevance of the one or more defects. For example, if the simulated aerial image is very similar to the reference image in the location of a defect, the defect can be assessed as not relevant. If the simulated aerial image differs from the reference image in the location of a defect, the defect can be assessed as relevant. The assessment step N3 can, additionally or alternatively, comprise the computation of a critical dimension (CD). The computed CD can be compared to a predefined CD. For example, if the computed CD is lower than the predefined CD in one or more locations these locations can be assessed as relevant defects.

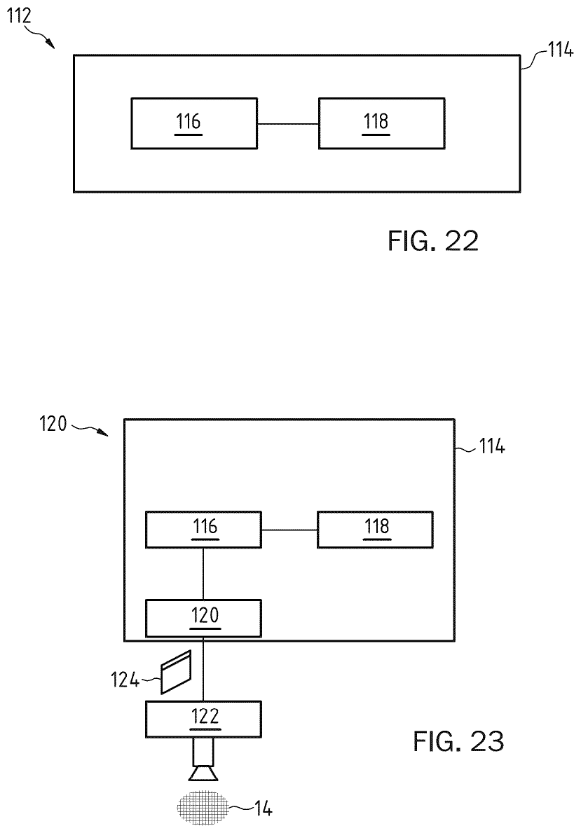

FIG. 22 illustrates a system 112 for simulating an aerial image of a model of a photolithography mask according to an embodiment of the invention, the system 112 comprising: a data analysis device 114 comprising at least one memory 118 and at least one processor 116 configured to perform the steps of a computer implemented method for simulating an aerial image of a model of a photolithography mask according to any of the embodiments described above. The processor 116 can, for example, be implemented as a central processing unit (CPU), graphics processing unit (GPU), or tensor processing unit (TPU).

FIG. 23 illustrates a system 120 for detecting defects in a photolithography mask according to an embodiment of the invention, the system 120 comprising: a subsystem 122 for obtaining an aerial image 124 of the photolithography mask; a data analysis device 114 comprising at least one memory 118 and at least one processor 116 configured to perform the steps of the computer implemented method 108 for detecting defects in a photolithography mask according to any of the embodiments of the invention described above. The subsystem 122 for obtaining an aerial image 124 of the photolithography mask can comprise an aerial image acquisition system. Alternatively, the subsystem 122 can comprise a database or any other memory comprising an aerial image 124 of the photolithography mask, and the subsystem 122 can be configured to load the aerial image 124 from the database or memory. The subsystem 122 for obtaining an aerial image 124 of the photolithography mask 14 can provide an aerial image 124 to the data analysis device 114. The data analysis device 114 includes a processor 116, e.g., implemented as a CPU or GPU. The processor 116 can receive the aerial image 124 via an interface 120. The processor 116 can load program code from a memory 118, e.g., program code for executing a computer implemented method for detecting defects in a photolithography mask according to any of the embodiments of the invention described above. The processor 116 can execute the program code.

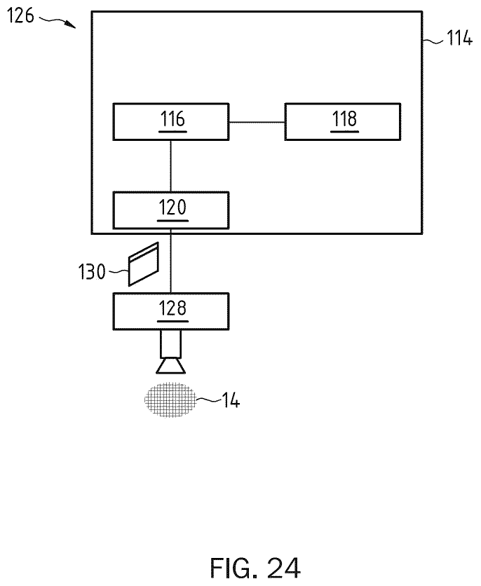

FIG. 24 illustrates a system 126 for assessing the relevance of defects in a photolithography mask according to an embodiment of the invention, the system 126 comprising: a subsystem 128 for obtaining a charged particle beam image 130 of the photolithography mask; a data analysis device 114 comprising at least one memory 118 and at least one processor 116 configured to perform the steps of the computer implemented method 110 for assessing the relevance of defects in a photolithography mask according to any of the embodiments of the invention described above. The subsystem 128 for obtaining a charged particle beam image 130 of the photolithography mask can comprise a charged particle beam device, for example, a Helium ion microscope (HIM), a cross-beam device including FIB and SEM or any charged particle imaging device. Alternatively, the subsystem 128 can comprise a database or any other memory comprising a charged particle beam image 130 of the photolithography mask, and the subsystem 128 can be configured to load the charged particle beam image 130 from the database or memory. The subsystem 128 for obtaining a charged particle beam image 130 of the photolithography mask 14 can provide a charged particle beam image 130 to the data analysis device 114. The data analysis device 114 includes a processor 116, e.g., implemented as a CPU or GPU. The processor 116 can receive the charged particle beam image 130 via an interface 120. The processor 116 can load program code from a memory 118, e.g., program code for a computer implemented method for assessing the relevance of defects in a photolithography mask according to an embodiment of the invention as described above. The processor 116 can execute the program code.

Any of the systems described above can contain a user interface, e.g., for showing loss plots, accuracy metrics, the training progress, or intermediate predictions to the user or for receiving input from the user, e.g., parameters of the machine learning model such as the learning rate, the incident angle Θ or physical parameters. Any of the systems described above can contain a database for loading and/or saving training data, validation data, intermediate results, pre-trained machine learning models for further training, trained machine learning models, e.g., for re-use in a different application, etc.

In some implementations, after the defects in a photolithography mask are detected using the methods and systems described above, the photolithography mask can be modified to repair or eliminate the defects. Repairing the defects can include, e.g., depositing materials on the photolithography mask using a deposition process, or removing materials from the photolithography mask using an etching process. Some defects can be repaired based on exposure with focused electron beams and adsorption of precursor molecules.

In some implementations, a repair device for repairing the defects on a photolithography mask can be configured to perform an electron beam-induced etching and/or deposition on the photolithography mask. The repair device can include, e.g. an electron source, which emits an electron beam that can be used to perform electron beam-induced etching or deposition on the object. The repair device can include mechanisms for deflecting, focusing and/or adapting the electron beam. The repair device can be configured such that the electron beam is able to be incident on a defined point of incidence on the photolithography mask.

The repair device can include one or more containers for providing one or more deposition gases, which can be guided to the photolithography mask via one or more appropriate gas lines. The repair device can also include one or more containers for providing one or more etching gases, which can be provided on the photolithography mask via one or more appropriate gas lines. Further, the repair device can include one or more containers for providing one or more additive gases that can be supplied to be added to the one or more deposition gases and/or the one or more etching gases.

The repair device can include a user interface to allow an operator to, e.g., operate the repair device and/or read out data.

The repair device can include a computer unit configured to cause the repair device to perform one or more of the methods described herein, based at least in part on an execution of an appropriate computer program.

In some implementations, the information about the defects serve as feedback to improve the process parameters of the manufacturing process for producing the photolithography masks. The process parameters can include, e.g., exposure time, focus, illumination, etc., For example, after the defects are identified from a first photolithography mask or first batch of photolithography masks, the process parameters of the manufacturing process are adjusted to reduce defects in a second mask or a second batch of masks.

In some implementations, a method for processing defects includes detecting at least one defect in a photolithography mask using the method for defect detection described above; and modifying the photolithography mask to at least one of reduce, repair, or remove the at least one defect.

For example, modifying the photolithography mask can include at least one of (i) depositing one or more materials onto the photolithography mask, (ii) removing one or more materials from the photolithography mask, or (iii) locally modifying a property of the photolithography mask.

For example, locally modifying a property of the photolithography mask can include writing one or more pixels on the photolithography mask to locally modify at least one of a density, a refractive index, a transparency, or a reflectivity of the photolithography mask.

In some implementations, a method of processing defects includes: processing a first photolithography mask using a manufacturing process that comprises at least one process parameter; detecting at least one defect in the first photolithography mask using the method for defect detection described above; and modifying the manufacturing process based on information about the at least one defect in the first photolithography mask that has been detected to reduce the number of defects or eliminate defects in a second photolithography mask to be produced by the manufacturing process.

For example, modifying the manufacturing process can include modifying at least one of an exposure time, focus, or illumination of the manufacturing process.

In some implementations, a method for processing defects includes: processing a plurality of regions on a first photolithography mask using a manufacturing process that comprises at least one process parameter, wherein different regions are processed using different process parameter values; applying the method for defect detection described above to each of the regions to obtain information about zero or more defects in the region; identifying, using a quality criterion or criteria, a first region among the regions based on information about the zero or more defects; identifying a first set of process parameter values that was used to process the first region; and applying the manufacturing process with the first set of process parameter values to process a second photolithography mask.

In some implementations, the data analysis device 114 can include one or more data processors (or one or more computing devices) configured to execute one or more programs that include a plurality of instructions according to the principles described above. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include millions or billions of transistors.

The methods described in this document can be carried out using one or more computing devices, which can include one or more data processors for processing data, one or more storage devices for storing data, and/or one or more computer programs including instructions that when executed by the one or more computing devices cause the one or more computing devices to carry out the method steps or processing steps. The one or more computing devices can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computing devices can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

In summary, in a general aspect, the invention relates to a computer implemented method 54 for simulating an aerial image 124 of a model of a photolithography mask 14 illuminated by incident electromagnetic waves 22, the method comprising: obtaining the model of the photolithography mask 14 wherein the model 56, 56′ of the photolithography mask 14 comprises an image 78, 79 containing image elements 88, in particular pixels or voxels, that each contain one or more property values at a corresponding location of the photolithography mask 14, and wherein the spatial resolution of the image 78, 79 is configured, such that at least one image element 88 corresponds to a location in the photolithography mask 14 containing two or more different property values for the same property of the photolithography mask 14, and/or such that image elements 88 differ in their physical size; simulating the propagation of the incident electromagnetic waves 22 through the model of the photolithography mask 14 using a machine learning model, wherein the machine learning model maps the model 56, 56′ of the photolithography mask 14 to a representation of an electromagnetic field 68 generated by the incident electromagnetic waves 22 on the photolithography mask 14; and obtaining the aerial image 124 of the model of the photolithography mask 14 by applying a simulation of an imaging process of a photolithography system or optical metrology system. The invention also relates to corresponding computer programs, computer-readable media and systems.

While some embodiments, examples or aspects have been described, other embodiments, examples, aspects, and combinations of features of different embodiments, examples and/or aspects are also within the scope of the following claims.

### REFERENCE NUMBER LIST

10, 10′ Photolithography system
12 Radiation source
14 Photolithography mask
16 Illumination optics
17 Projection optics
18 Wafer plane
19 Projection section
20 Near field
22 Electromagnetic wave
24 Grating
25 Absorber section
26 Absorber structures
27 Mask carrier section
28 Non-absorber structures
30 Absorber plane
32 Mask carrier plane
34 Base plane
38 Multilayer
40 Optical thin film
42 Capping layer
46 Substrate layer
48 Mask carrier
50 Main propagation direction
52 Near field plane
54 Computer implemented method
56, 56′ Model
58 Boundary
60 Left boundary
62 Right boundary
64 Encoder
66 Decoder
67 Complex incident electromagnetic field
68 Representation of an electromagnetic field
69 Complex total electromagnetic field
70 Incident angle
72 Training data
74 Neural network
76 Bottleneck
78 Cross section image
79 Voxel volume
80, 80′ Side wall angle
82 Side wall variation area
84 Side wall
86 Line
88 Image element
90 First layer
92 Second layer
94 Outgoing electromagnetic waves
96 Reflected electromagnetic waves
98 Computer implemented method
100 Vertical axis
102 Horizontal axis
104 Training dataset
106 Validation dataset
108 Computer implemented method
110 Computer implemented method
112 System
114 Data analysis device
116 Memory
118 Processor
120 System
122 Subsystem
124 Aerial image
126 System
128 Subsystem
130 Charged particle beam image

What is claimed is:

1. A computer implemented method for simulating an aerial image of a model of a photolithography mask, the photolithography mask comprising a mask carrier and a grating, the grating comprising absorber structures and non-absorber structures forming a pattern on at least a portion of the mask carrier, the photolithography mask comprising an absorber section extending between an absorber plane and a mask carrier plane of the photolithography mask and a mask carrier section extending between the mask carrier plane and a base plane of the photolithography mask, wherein the photolithography mask is illuminated by incident electromagnetic waves, the method comprising:
obtaining the model of the photolithography mask, wherein the model of the photolithography mask comprises an image containing image elements, the image elements comprising pixels or voxels, that each contain one or more property values for one or more properties at a corresponding location of the photolithography mask, and wherein the spatial resolution of the image is configured, such that at least one image element corresponds to a location in the photolithography mask containing two or more different property values for the same property of the photolithography mask, and/or such that image elements differ in their physical size;
simulating the propagation of the incident electromagnetic waves through the model of the photolithography mask using a machine learning model, wherein the machine learning model maps the model of the photolithography mask to a representation of an electromagnetic field generated by the incident electromagnetic waves on the photolithography mask; and
obtaining the aerial image of the model of the photolithography mask by applying a simulation of an imaging process of a photolithography system or optical metrology system within a projection section to the representation of the electromagnetic field in a near field plane next to the absorber plane, wherein the projection section extends between the near field plane and a wafer plane.

2. The method of claim 1, wherein the machine learning model was trained using a loss function comprising one or more partial differential equations describing properties of the representation of the electromagnetic field within the photolithography mask.

3. The method of claim 2, wherein the one or more partial differential equations are derived from Maxwell's equations or from a Helmholtz equation.

4. The method of claim 1, wherein the image elements of the image of the model of the photolithography mask contain one or more property values of material properties within the photolithography mask.

5. The method of claim 1, wherein the image elements of the image of the model of the photolithography mask contain refractive indices of materials within the photolithography mask.

6. The method of claim 1, wherein the image elements of the image of the model of the photolithography mask contain characteristic function values of materials within the photolithography mask.

7. The method of claim 3, wherein at least one image element corresponds to a location in the photolithography mask containing two or more different material property values for the same material property.

8. The method of claim 7, wherein the material property value of the at least one image element that corresponds to a location in the photolithography mask containing two or more different material property values for the same material property indicates an effective material property value of the two or more different material property values for the same material property.

9. The method of claim 1, wherein image elements differ in their physical size.

10. The method of claim 9, wherein the model of the photolithography mask comprises an absorber section, and wherein the physical sizes of at least some of the image elements in the absorber section are configured such that boundaries of these image elements coincide with boundaries of absorber structures in the absorber section.

11. The method of claim 1, wherein the photolithography mask is an EUV photolithography mask, and wherein the mask carrier section comprises a multilayer in the form of a stack of optical thin films for reflecting the electromagnetic waves.

12. The method of claim 11, wherein the model of the photolithography mask comprises a multilayer, and wherein the physical sizes of image elements differ in at least two different layers of the multilayer.

13. The method of claim 12, wherein the physical sizes of at least some of the image elements are configured such that boundaries of these image elements coincide with boundaries of layers in the multilayer.

14. A computer implemented method for simulating an aerial image of a model of an EUV photolithography mask, the photolithography mask comprising a mask carrier and a grating, the grating comprising absorber structures and non-absorber structures forming a pattern on at least a portion of the mask carrier, the photolithography mask comprising an absorber section extending between an absorber plane and a mask carrier plane of the photolithography mask and a mask carrier section extending between the mask carrier plane and a base plane of the photolithography mask, wherein the mask carrier section comprises a multilayer in the form of a stack of optical thin films for reflecting the electromagnetic waves, and wherein the photolithography mask is illuminated by incident electromagnetic waves, the method comprising:
obtaining the model of the photolithography mask;
simulating the propagation of the incident electromagnetic waves through the model of the photolithography mask using a machine learning model, wherein the machine learning model maps the model of the photolithography mask to a representation of an electromagnetic field generated by the incident electromagnetic waves on the photolithography mask, and wherein the machine learning model simulates the propagation of the electromagnetic waves within the absorber section of the photolithography mask, and wherein the propagation of the electromagnetic waves within the multilayer is computed analytically or with a numerical method not involving machine learning; and
obtaining the aerial image of the model of the photolithography mask by applying a simulation of an imaging process of a photolithography system or optical metrology system within a projection section to the representation of the electromagnetic field in a near field plane next to the absorber plane, wherein the projection section extends between the near field plane and a wafer plane.

15. The method of claim 14, wherein the propagation of the electromagnetic waves within the multilayer is computed using a boundary condition that describes the reflection of the electromagnetic waves at a plane parallel to the mask carrier plane within the mask carrier section.

16. The method of claim 14, wherein the propagation of the electromagnetic waves within the multilayer is implemented using an absorbing boundary condition, in particular a perfectly matched layer boundary condition, and a reflection term describing the electromagnetic waves reflected by the multilayer at a plane parallel to the mask carrier plane within the mask carrier section.

17. The method of claim 1, wherein the model describes the photolithography mask at least partially in a dimension orthogonal to the mask carrier plane.

18. A computer implemented method for training a machine learning model for simulating the propagation of electromagnetic waves through a model of a photolithography mask according to any one of the preceding claims, the method comprising:
generating models of photolithography masks as training data, the photolithography masks comprising a mask carrier and a grating, the grating comprising absorber structures and non-absorber structures forming a pattern on at least a portion of the mask carrier, the photolithography masks further comprising an absorber section extending between an absorber plane and a mask carrier plane of the photolithography mask and a mask carrier section extending between the mask carrier plane and a base plane of the photolithography mask;
iteratively presenting one or more models of photolithography masks from the training data to the machine learning model; and
evaluating the loss function and modifying the parameters of the machine learning model.

19. The method of claim 18, wherein the loss function comprises one or more partial differential equations describing properties of the representation of the electromagnetic field within the photolithography mask.

20. The method of claim 19, wherein the one or more partial differential equations are derived from Maxwell's equations or from a Helmholtz equation.

21. The method of claim 18, wherein the loss function is evaluated using an approximation scheme of derivatives of the representation of the electromagnetic field that takes into account the physical sizes of the image elements, in particular approximation schemes relying on finite differences or finite elements.

22. The method of claim 18, wherein the machine learning model simulates the propagation of electromagnetic waves within the absorber section of the photolithography mask, and wherein the loss function computes the propagation of the electromagnetic waves within the mask carrier section analytically or with a numerical method not involving machine learning.

23. The method of claim 22, wherein the photolithography mask is an EUV photolithography mask, and wherein the loss function comprises a boundary condition that describes the reflection of the electromagnetic waves at a plane parallel to the mask carrier plane within the mask carrier section.

24. The method of claim 22, wherein the loss function comprises a perfectly matched layer boundary condition and a reflection term describing the electromagnetic waves reflected by the multilayer at a plane parallel to the mask carrier plane within the mask carrier section.

25. A computer implemented method for detecting defects in a photolithography mask, the method comprising:
obtaining an aerial image of the photolithography mask;
simulating an aerial image of a model of the photolithography mask using a method of claim 1;
detecting defects in the photolithography mask by comparing the obtained aerial image to the simulated aerial image.

26. The method of claim 25, wherein the defects comprise edge placement errors, and wherein the edge placement errors are detected by registering the obtained aerial image to the simulated aerial image.

27. A computer implemented method for assessing the relevance of defects in a photolithography mask, the method comprising:
providing a charged particle beam image of the photolithography mask comprising one or more defects;
simulating an aerial image of a model of the photolithography mask using a method of claim 1, wherein the charged particle beam image is used as a model of the photolithography mask;
assessing the relevance of the one or more defects in the photolithography mask using the simulated aerial image.

28. A computer-readable medium, having stored thereon a computer program executable by a computing device, the computer program comprising code for executing a method of claim 1.

29. A computer program product comprising instructions which, when the program is executed by a computer, cause the computer to carry out a method of claim 1.

30. A system for simulating an aerial image of a model of a photolithography mask, the system comprising a data analysis device comprising at least one memory and at least one processor configured to perform the steps of a computer implemented method according to claim 1.

31. A system for detecting defects in a photolithography mask, the system comprising:
a subsystem for obtaining an aerial image of the photolithography mask; and
a data analysis device comprising at least one memory and at least one processor configured to perform the steps of the computer implemented method of claim 25.

32. A system for assessing the relevance of defects in a photolithography mask, the system comprising:
a subsystem for obtaining a charged particle beam image of the photolithography mask; and
a data analysis device comprising at least one memory and at least one processor configured to perform the steps of the computer implemented method of claim 27.
